(19) United States
(12) Patent Application Publication
(10) Pub. No.: US 2009/0194319 A1
(43) Pub. Date: Aug. 6, 2009

(54) PHOTOCURABLE RESIN COMPOSITION, DRY FILM, CURED PRODUCT, AND PRINTED CIRCUIT BOARD

(76) Inventors: Nobuhito ITOH, Hiki-gun (JP); Yoko Shibasaki, Hiki-gun (JP); Kenji Kato, Hiki-gun (JP); Masao Arima, Hiki-gun (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/389,987

(22) Filed: Feb. 20, 2009

Related U.S. Application Data
(63) Continuation of application No. PCT/JP08/51577, filed on Jan. 31, 2008.

(30) Foreign Application Priority Data
Mar. 29, 2007 (JP) 2007-089571

(51) Int. Cl. H05K 1/00; G03F 7/004

(52) U.S. Cl. 174/250; 430/281.1

(57) ABSTRACT

Provided is a photocurable resin composition developable with a rare alkali solution, including a carboxylic acid-containing resin (A), a coloring agent (B) composed of a compound having an aminoantraquinone skeleton, a photopolymerization initiator (C), and a compound (D) having two or more ethylenically unsaturated groups within one molecule thereof, the composition being sufficiently colored while controlling absorption in the ultraviolet region using the coloring agent composed of a compound having an aminoantraquinone skeleton, having high sensitivity to ultraviolet and laser exposure, and providing good dry tack in a state of a dry coating film.

### CROSS-REFERENCE TO RELATED APPLICATIONS

This is a Continuation Application of PCT Application No. PCT/JP2008/051577, filed Jan. 31, 2008, which was published under PCT Article 21 (2) in Japanese.

This application is based upon and claims the benefit of priority from prior Japanese Patent Application No. 2007-089571, filed Mar. 29, 2007, the entire contents of which are incorporated herein by reference.

### BACKGROUND OF THE INVENTION

1. Field of the Invention

The present invention relates to a photocurable resin composition developable with a rare alkali solution, specifically, a solder resist composition to be exposed to ultraviolet light or laser beams, a dry film and a cured product of the composition, and a printed circuit board including the composition.

2. Description of the Related Art

With the rapid advance in semiconductor components, electronic appliances are required to be smaller in size and lighter in weights, and to have higher performance, and more functions. Along with the trend, printed circuit boards are also required to have higher densities and more surface mount components. Production of high density printed circuit boards usually uses photosensitive solder resists. Dry film photosensitive solder resists and liquid photosensitive solder resists are developed for these applications.

These solder resists have been colored in green or blue with a phthalocyanine compound as a coloring agent (Patent Document 1: Jpn. Pat. Appln. KOKAI Publication No. 2000-7974).

However, exposure of the coloring agent to ultraviolet light causes the following problem. That is, a phthalocyanine compound has strong absorption in the ultraviolet region, and its absorption markedly varies in the ultraviolet region from 350 nm to 400 nm. If the absorption in the ultraviolet region is strong, it is difficult to achieve deep curing. In addition, various ultraviolet exposure devices (lamps) have different ultraviolet wavelength distributions. Therefore, if the variation of absorption in the ultraviolet region is great, it is difficult to develop a solder resist giving equal resolution performance for different ultraviolet exposure devices.

Further, exposure of the coloring agent to laser beams, which is becoming widespread recently, causes the following problem. That is, laser exposure requires a highly sensitive resist, and at the same time needs to obtain photoresist profiles having a high resolving power and a good shape. Laser exposure uses light having a single wavelength different from ultraviolet lamp exposure. Therefore, for laser exposure, the absorption of light at the wavelength by the resist is important, and the resist sensitivity is determined by effective absorption of light from the light source by the photopolymerization initiator. However, the coloring agent absorbs light as described above, thus the presence of the coloring agent is not only unfavorable for the enhancement of sensitivity, but also inhibits transmission of light to the bottom, which causes undercutting. As described above, the phthalocyanine compound has strong absorption in the ultraviolet region, thus the addition of phthalocyanine in an amount enough to achieve sufficient coloring will cause undercutting. This problem can be solved by decreasing the amount of the photopolymerization initiator, but this decrease results in the failure of exposure at high sensitivity. Enough sensitivity can be achieved by limiting the amount of the phthalocyanine compound so as not to cause undercutting, and increasing the concentration of the photopolymerization initiator, but the problem that coloration of the solder resist is insufficient remains.

If coloration of the solder resist is insufficient, stains and discoloration of the copper circuit formed on the print circuit board are easy to see, which results in a marked deterioration in the yield of such printed circuit boards. Recently, the mounting process after printed wiring is automated, and components are mounted by machine. During image recognition, misrecognition of the solder resist and copper circuit can occur. This phenomenon also occurs during AOI (Automatic Optical Inspection), which is the final inspection of a printed circuit board.

Commercially available solder resists can be expressed by the CIE L*a*b* system, though the values vary depending on the film thickness and pretreatment of the copper substrate; green solder resists have an L* value of 40 to 60, an a* value of −10 to −28, and a b* value of 6 to 18, and blue solder resists have an L* value of 40 to 60, an a* value of −10 to −28, and a b* value of −6 to −18. More preferred green and blue solder resists have an L* value of 40 to 50 from the viewpoint of AOI, and should be colored to that degree.

If a solder resist composition in the solid state (a dry film after evaporation of the solvent) has a low softening point, its sensitivity is high. However, if the softening point is too low, the film gives poor dry tack, so that can be sticky during exposure in close contact with a photographic tool, transfer of the coated substrate to the exposure device, or removal of a protective film from the dry film.

### BRIEF SUMMARY OF THE INVENTION

### Problems to be Solved by the Invention

The present invention has been accomplished in view of the above-described problems, and is intended to provide a composition which is sufficiently colored while controlling absorption in the ultraviolet region, highly sensitive to ultraviolet and laser exposure, and provides good dry tack in the form of a dry coating film.

In order to solve the problems the Invention has features as follows.

### Means for Solving the Problems

(1) A photocurable resin composition developable with a rare alkali solution, comprising a carboxylic acid-containing resin (A), a coloring agent (B) composed of a compound having an aminoantraquinone skeleton, a photopolymerization initiator (C), and a compound (D) having two or more ethylenically unsaturated groups within one molecule thereof.

(2) The photocurable resin composition according to claim 1 developable with a rare alkali solution, wherein the aminoantraquinone compound (B) is expressed by the general formula (I):

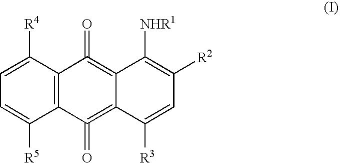

wherein R¹ represents a linear or branched alkyl group, an alkyl-substituted or unsubstituted phenyl group, a cyclohexyl group, a linear or branched alkyl group through the mediation of a carbonyl group, a substituted or unsubstituted phenyl group; R² represents a hydrogen atom, a hydroxy group, a cyclohexyl group, a linear or branched alkyl group, a substituted or unsubstituted phenyl group, the R² being bonded directly or through the mediation of an NH group, and the R² may be in the form a ring together with the R¹; R³, R⁴, and R⁵ each independently represent a hydrogen atom, a hydroxy group, a cyclohexyl group, a linear or branched alkyl group, a substituted or unsubstituted phenyl group, a linear or branched alkyl group through the mediation of an NH group, an alkyl-substituted or unsubstituted phenyl group, a cyclohexyl group, a linear or branched alkyl group through the mediation of an amide group, a substituted or unsubstituted phenyl group.

(3) The photocurable resin composition according to claim 1 or 2 developable with a rare alkali solution, wherein the coloring agent (B) composed of a compound having an aminoantraquinone skeleton comprises two or more coloring agents having different structures.

(4) The photocurable resin composition according to (1) developable with a rare alkali solution, wherein the coloring agent (B) composed of a compound having an aminoantraquinone skeleton is expressed by the general formula (II):

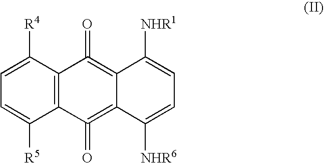

wherein R¹ represents a linear or branched alkyl group, an alkyl-substituted or unsubstituted phenyl group, a cyclohexyl group, a linear or branched alkyl group through the mediation of a carbonyl group, a substituted or unsubstituted phenyl group; R⁴ and R⁵ each independently represent a hydrogen atom, a hydroxy group, a cyclohexyl group, a linear or branched alkyl group, a substituted or unsubstituted phenyl group, a linear or branched alkyl group through the mediation of an NH group, an alkyl-substituted or unsubstituted phenyl group, a cyclohexyl group, a linear or branched alkyl group through the mediation of an amide group, a substituted or unsubstituted phenyl group; and R⁶ represents a linear or branched alkyl group, an alkyl-substituted or unsubstituted phenyl group, a cyclohexyl group, a linear or branched alkyl group through the mediation of a carbonyl group, a substituted or unsubstituted phenyl group.

(5) The photocurable resin composition according to (1) developable with a rare alkali solution, wherein the coloring agent (B) composed of a compound having an aminoantraquinone skeleton is a single compound or mixture selected from the group consisting of coloring agents having green and blue colors.

(6) The photocurable resin composition according to (1), wherein the photopolymerization initiator (C) is at least one selected from the group consisting of oxime ester-based photopolymerization initiators expressed by the general formula (III):

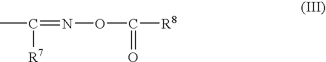

wherein R⁷ represents a hydrogen atom, a phenyl group (which may be substituted with an alkyl group having 1 to 6 carbon atoms, a phenyl group, or a halogen atom), an alkyl group having 1 to 20 carbon atoms (which may be substituted with one or more hydroxy groups, or contain one or more oxygen atoms in the middle of the alkyl chain), a cycloalkyl group having 5 to 8 carbon atoms, an alkanoyl group or benzoyl group having 2 to 20 carbon atoms (which may be substituted with an alkyl group having 1 to 6 carbon atoms or a phenyl group); R⁸ represents a phenyl group (which may be substituted with an alkyl group having 1 to 6 carbon atoms, a phenyl group, or a halogen atom), an alkyl group having 1 to 20 carbon atoms (which may be substituted with one or more hydroxy groups, or contain one or more oxygen atoms in the middle of the alkyl chain), a cycloalkyl group having 5 to 8 carbon atoms, an alkanoyl group or benzoyl group having 2 to 20 carbon atoms (which may be substituted with an alkyl group having 1 to 6 carbon atoms or a phenyl group);

α-amino acetophenone-based photopolymerization initiators expressed by the general formula (IV):

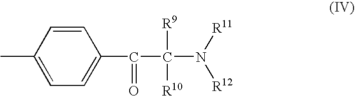

wherein R⁹ and R¹⁰ each independently represent an alkyl group or arylalkyl group having 1 to 12 carbon atoms, R¹¹ and R¹² are each independently a hydrogen atom, an alkyl group having 1 to 6 carbon atoms, or a cyclic alkyl ether group composed of two rings;

acyl phosphine oxide-based photopolymerization initiators expressed by the general formula (V):

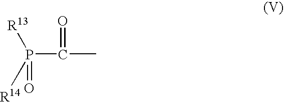

wherein R¹³ and R¹⁴ each independently represent a linear or branched alkyl group having 1 to 10 carbon atoms, a cyclohexyl group, a cyclopentyl group, an aryl group, an alkoxy group, or an aryl group substituted with a halogen atom, an alkyl group, or an alkoxy group, one of the R¹³ or R¹⁴ may represent an R—C(═O)-group (wherein R is a hydrocarbon group having 1 to 20 carbon atoms).

(7) The photocurable resin composition according to (6), wherein the oxime ester-based photopolymerization initiator (C) expressed by the general formula (III) is expressed by the following formula (VI):

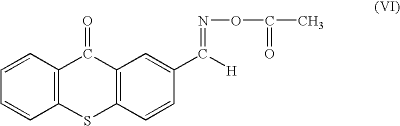

(8) The photocurable resin composition according to (6), wherein the oxime ester-based photopolymerization initiator (C) expressed by the general formula (III) is expressed by the following formula (VII):

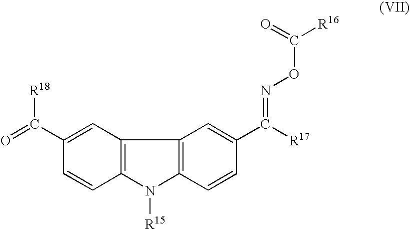

wherein R¹⁵ represents a hydrogen atom, a halogen atom, an alkyl group having 1 to 12 carbon atoms, a cyclopentyl group, a cyclohexyl group, a phenyl group, a benzyl group, a benzoyl group, an alkanoyl group having 2 to 12 carbon atoms, an alkoxycarbonyl group having 2 to 12 carbon atoms (when the alkoxyl group is composed of an alkyl group having 2 or more carbon atoms, the alkyl group may be substituted with one or more hydroxy groups, or contain one or more oxygen atoms in the middle of the alkyl chain), or a phenoxy carbonyl group; R¹⁶ and R¹⁸ each independently represent a phenyl group (which may be substituted with an alkyl group having 1 to 6 carbon atoms, a phenyl group, or a halogen atom), an alkyl group having 1 to 20 carbon atoms (which may be substituted with one or more hydroxy groups, or contain one or more oxygen atoms in the middle of the alkyl chain), a cycloalkyl group having 5 to 8 carbon atoms, an alkanoyl group or benzoyl group having 2 to 20 carbon atoms (which may be substituted with an alkyl group having 1 to 6 carbon atoms or a phenyl group), and R¹⁷ represents a hydrogen atom, a phenyl group (which may be substituted with an alkyl group having 1 to 6 carbon atoms, a phenyl group, or a halogen atom), an alkyl group having 1 to 20 carbon atoms (which may be substituted with one or more hydroxy groups, or contain one or more oxygen atoms in the middle of the alkyl chain), a cycloalkyl group having 5 to 8 carbon atoms, an alkanoyl group or benzoyl group having 2 to 20 carbon atoms (which may be substituted with an alkyl group having 1 to 6 carbon atoms or a phenyl group).

(9) The photocurable resin composition according to (1), which further comprises a thermosetting component (E).

(10) The photocurable resin composition according to (1), wherein the color of the composition is within the range of green to blue.

(11) A photocurable dry film obtainable by applying the photocurable resin composition according to (1) to a carrier film, and then drying the coating film.

(12) A cured product obtainable by photocuring the photocurable resin composition according to (1) on copper.

(13) A cured product obtainable by photocuring the photocurable resin composition according to (1).

(14) A printed circuit board obtainable by photocuring the photocurable resin composition according to (1), and then thermally curing the cured product.

(15) A printed circuit board comprising the coloring agent according to (1) composed of a compound having an aminoantraquinone skeleton.

(16) A cured product obtainable by photocuring the photocurable resin composition according to the dry film of (11) on copper.

(17) A cured product obtainable by photocuring the photocurable resin composition according to the dry film of (11).

(18) A printed circuit board obtainable by photocuring the photocurable resin composition according to the dry film of (11), and then thermally curing the cured product.

### (Definition of Colors of Composition and Solder Resist)

The colors of the composition and solder resist can be differentiated by the hue circle based on JIS Z 8721 and symbols of the Munsell hue circle (New Basic Color Chart Series 2, Munsell system, supervised by Japan Color Research Institute, published by Japan Color Enterprise Co., Ltd.). The colors are within the following ranges (see Munsell hue circle in FIG. 1).

| | |
|---|---|
| Red | from 7RP to less than 9R |
| Orange | from 9R to less than 7YR |
| Yellow | from 7YR to less than 9Y |
| Green | from 9Y to less than 5BG |
| Blue | from 5BG to less than 3P |
| Purple | from 3P to less than 7RP |

In the claims and present description, “from green to blue” refers to the range from 9Y to 3P in the Munsell hue circle.

The chroma is preferably 1 or more and less than 16, and more preferably 2 or more and less than 15, and the lightness is preferably 1 or more and less than 9, and more preferably 2 or more and less than 9, though these values vary depending on the base material (glass epoxy substrate, copper circuit, or surface-treated copper circuit). (The chroma and lightness are based on JIS Z 8102 and JIS Z 8721).

Further, these values are preferably measured for a solder resist having a thickness of 20 to 30 μm on a copper circuit.

In the present invention, the term printed circuit board refers to an electrically insulating substrate having thereon a conductor pattern formed by a printing technique such as screen printing or photographic etching, and include rigid circuit boards and flexible circuit boards.

### ADVANTAGEOUS EFFECT OF THE INVENTION

The present invention provides a composition being sufficiently colored while having a controlled absorption in the ultraviolet region using a coloring agent composed of a compound having an aminoantraquinone skeleton, and highly sensitive to ultraviolet and laser exposure, and providing good dry tack in the form of a dry coating film.

### BRIEF DESCRIPTION OF THE SEVERAL VIEWS OF THE DRAWING

FIG. 1 is an explanatory drawing showing a Munsell hue circle.

FIG. 2 shows schematic views of sectional forms of the resin compositions obtained through exposure and development; A to E show line forms of different grades. In FIG. 2, 1a indicates the designed value of the line width, 1b indicates the resin composition after exposure and development, and 1c indicates a substrate.

FIG. 3 is a characteristic chart of the absorbance of phthalocyanine blue Pigment Blue 15:3 with wavelength as the ordinate and absorbance as the abscissa.

FIG. 4 is a characteristic chart of the compound expressed by the general formula (VIII) with wavelength as the ordinate and absorbance as the abscissa.

FIG. 5 is a characteristic chart of the compound expressed by the general formula (IX) with wavelength as the ordinate and absorbance as the abscissa.

FIG. 6 is a characteristic chart of the compound expressed by the general formula (XIII) with wavelength as the ordinate and absorbance as the abscissa.

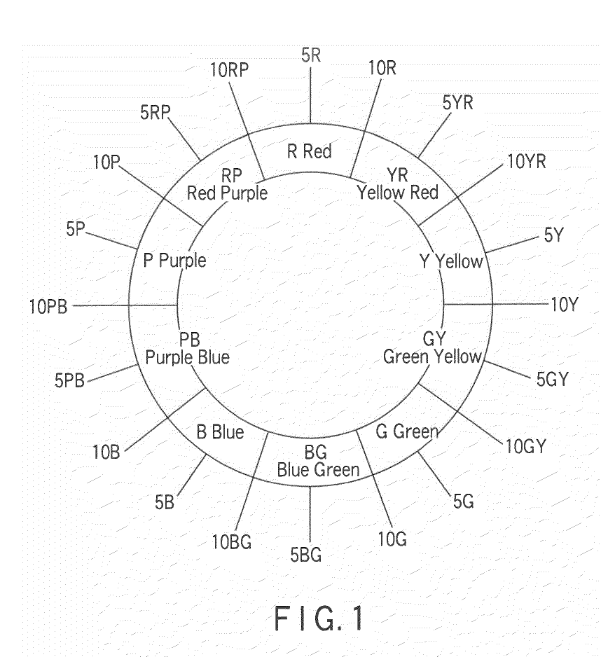

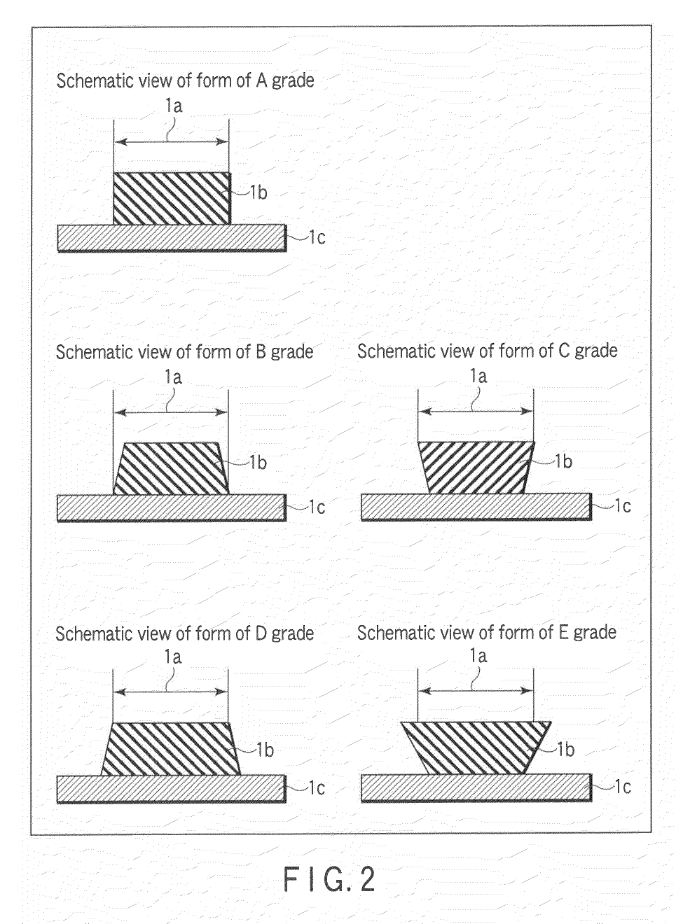

### DETAILED DESCRIPTION OF THE INVENTION

The constituents of the photocurable resin composition of the present invention are described below in detail.

(A) Carboxylic Acid-Containing Resin

The carboxylic acid-containing resin (A) contained in the photocurable resin composition of the present invention may be a known resin compound containing carboxylic acid within one molecule thereof. From the viewpoints of photocurability and development resistance, more preferred is a carboxylic acid-containing photosensitive resin (A′) having an ethylenically unsaturated double bond within one molecule thereof.

Specific examples of the resin include, but not limited to, the following:

(1) carboxylic acid-containing copolymer resins prepared by copolymerization of an unsaturated carboxylic acid such as (meth)acrylic acid with one or more other compound having an unsaturated double bond;

(2) carboxylic acid-containing photosensitive resins prepared by addition of an ethylenically unsaturated group as a pendant group to a copolymer of an unsaturated carboxylic acid such as (meth)acrylic acid and one or more other compounds having an unsaturated double bond using a compound having an epoxy group and an unsaturated double bond such as glycidyl (meth)acrylate or 3,4-epoxycyclohexylmethyl (meth)acrylate, or (meth)acrylic acid chloride;

(3) carboxylic acid-containing photosensitive resins prepared by reaction of an unsaturated carboxylic acid such as (meth)acrylic acid with a copolymer of a compound having an epoxy group and an unsaturated double bond, such as glycidyl (meth)acrylate or 3,4-epoxycyclohexylmethyl (meth)acrylate, and another compound having an unsaturated double bond, followed by reaction of the resultant secondary hydroxy groups with a polybasic acid anhydride;

(4) carboxylic acid-containing photosensitive resins prepared by reaction of a compound having a hydroxy group and an unsaturated double bond, such as a 2-hydroxyethyl (meth)acrylate, with a copolymer of an acid anhydride having an unsaturated double bond, such as maleic anhydride, and another compound having an unsaturated double bond;

(5) carboxylic acid-containing photosensitive resins prepared by reaction of a polyfunctional epoxy compound with an unsaturated monocarboxylic acid, followed by reaction of the resultant hydroxy group with a saturated or unsaturated polybasic acid anhydride;

(6) photosensitive resins containing a hydroxy group and carboxylic acid prepared by reaction of a hydroxy group-containing polymer such as a polyvinyl alcohol derivative with a saturated or unsaturated polybasic acid anhydride, followed by reaction of the resultant carboxylic acid with a compound containing an epoxy group and an unsaturated double bond within one molecule thereof;

(7) carboxylic acid-containing photosensitive resins prepared by reaction of a polyfunctional epoxy compound with an unsaturated monocarboxylic acid and a compound having within one molecule thereof at least one alcoholic hydroxy group and one reactive group other than the alcoholic hydroxy group which reacts with an epoxy group, followed by reaction of the reaction product with a saturated or unsaturated polybasic acid anhydride;

(8) carboxylic acid-containing photosensitive resins prepared by reaction of a polyfunctional oxetane compound having at least two oxetane rings within one molecule thereof with an unsaturated monocarboxylic acid, followed by reaction of the primary hydroxy group within the resultant modified oxetane resin with a saturated or unsaturated polybasic acid anhydride; and

(9) carboxylic acid-containing photosensitive resins prepared by reaction of a polyfunctional epoxy resin with an unsaturated monocarboxylic acid, and then a polybasic acid anhydride, followed by reaction of the resultant carboxylic acid-containing resin with a compound having one oxirane ring and one or more ethylenically unsaturated groups within one molecule thereof.

Among these examples, preferred are the carboxylic acid-containing resins of (2), (5), and (7), and particularly preferred are the carboxylic acid-containing photosensitive resins of (9) from the viewpoints of photocurability and cured coating film properties.

In the present description, the term “(meth)acrylate” is a generic name for acrylates, methacrylates, and mixtures thereof, and the same shall apply to other similar representations.

The carboxylic acid-containing resin (A) as described above has many free carboxylic groups in the side chain of the backbone polymer, and thus is developable with a rare alkali aqueous solution.

The acid value of the carboxylic acid-containing resin (A) is from 40 to 200 mgKOH/g, and more preferably from 45 to 120 mgKOH/g. If the acid value of the carboxylic acid-containing resin is less than 40 mgKOH/g, alkali development is difficult, and if the acid value is more than 200 mgKOH/g, the exposed areas can be excessively dissolved by the developing solution to cause excessive thinning of lines, or the exposed areas and unexposed areas can be indiscriminately dissolved with the developing solution, which hinders normal drawing of a resist pattern, and therefore these cases are not desirable.

The weight average molecular weight of the carboxylic acid-containing resin (A) is usually from 2,000 to 150,000, and preferably from 5,000 to 100,000, though the values depend on the resin skeleton. If the weight average molecular weight is less than 2,000, the tack free performance and moisture resistance of the coating film after exposure may be poor, which can result in thinning of the coating film and markedly poor resolution during development. On the other hand, if the weight average molecular weight is more than 150,000, developability may be markedly poor, and storage stability may also be poor.

The content of the carboxylic acid-containing resin (A) is from 20 to 60% by mass, preferably 30 to 50% by mass with reference to the whole composition. If the content is below the range, the strength of the coating film may deteriorate. On the other hand, if the content is beyond the range, viscosity may be excessive, or application properties may deteriorate.

(B) Coloring Agent Composed of a Compound Having an Aminoantraquinone Skeleton

The compound having an aminoantraquinone skeleton expressed by the general formula (I) has a weak absorption in the ultraviolet region, and the variation in the absorption from 350 to 400 nm is small. Therefore, the use of the compound as the coloring agent allows the photopolymerization initiator to effectively absorb the light emitted from the light source used herein. As a result of this, the composition has increased sensitivity, and transmits light to the bottom, thereby achieving deep curability.

In particular, when a mixture of a plurality of aminoantraquinone compounds having different structures is used as the coloring agent, sufficient coloring is achieved with a smaller amount of the agent in comparison with the case where a single aminoantraquinone compound is used as the coloring agent, which contributes to the increase of sensitivity and deep curability. Since an aminoantraquinone compound is soluble or sparingly soluble in a solvent, it is uniformly dispersed or dissolved in a solvent. However, an aminoantraquinone compound is extremely poorly soluble in the carboxylic acid-containing resin as a component of the composition of the present invention. Therefore, when the solvent is evaporated, aminoantraquinone dissolved therein tends to deposit to form granular crystals. On this account, when a single aminoantraquinone compound is used as the coloring agent, its amount must be small to prevent the formation of granular crystals. On the other hand, it was found that the use of a plurality of aminoantraquinone compounds having different structures less likely causes the formation of granular crystals in a dry state, and achieves sufficient coloring of the resultant solder resist. These findings are novel findings made by the inventors of the present invention.

Among the compounds having an aminoantraquinone skeleton expressed by the general formula (I), those expressed by the general formula (II) having a plurality of substituents are suitable for improving dry tack of the dry coating film. According to the inventors, this is likely due to the face that the interaction between the coloring agent composed of the above-described compound and the carboxylic acid-containing resin increases the softening point of the coating film.

Of the coloring agents composed of the aminoantraquinone compound (B), blue and green coloring agents are preferably the compounds expressed by the general formulae (VIII) to (XIII).

The content of the coloring agent is from 0.010 to 5 parts by mass, preferably from 0.1 to 3 parts by mass, and particularly preferably from 0.5 to 2 parts by mass with reference to 100 parts by mass of the carboxylic acid-containing resin (A) thereby achieving sufficient coloring, high sensitivity, high deep curability, and dry tack.

When a compound containing a plurality of aminoantraquinone skeletons having different structures is used, the content of the compound may be increased thereby enhancing the coloring effect. In this case, the content of the compound is from 0.010 to 5 parts by mass, preferably from 0.1 to 3 parts by mass, and particularly preferably from 0.5 to 2 parts by mass with reference to 100 parts by mass of the carboxylic acid-containing resin (A).

According to an aspect of the present invention, inclusion of coloring agents (pigments, dyes, or colorants) is allowed without defeating the object of the present invention. Examples of the coloring agent include the following.

### Blue Coloring Agent

The blue coloring agent may be phthalocyanine-based or anthraquinone-based one. Pigment-based ones include compounds classified as pigments, and specific examples thereof include the following indicated with color index numbers (C.I.; published by The Society of Dyers and Colourists):

### Pigment Blue 15, Pigment Blue 15:1, Pigment Blue 15:2, Pigment Blue 15:3, Pigment Blue 15:4, Pigment Blue 15:6, Pigment Blue 16, and Pigment Blue 60.

Examples of dye-based ones include:

Solvent Blue 35, Solvent Blue 45, Solvent Blue 63, Solvent Blue 68, Solvent Blue 70, Solvent Blue 83, Solvent Blue 87, Solvent Blue 94, Solvent Blue 97, Solvent Blue 101, Solvent Blue 104, Solvent Blue 122, Solvent Blue 136, Solvent Blue 67, and Solvent Blue 70. In addition to the above examples, metal-substituted or unsubstituted phthalocyanine compound may also be used.

### Green Coloring Agent

The green coloring agent may be phthalocyanine-based, anthraquinone-based, or perylene-based.

Specific examples thereof include:

Pigment Green 7, Pigment Green 36, Solvent Green 3, Solvent Green 5, Solvent Green 20, and Solvent Green 28. In addition to the above examples, metal-substituted or unsubstituted phthalocyanine compounds may also be used.

### Yellow Coloring Agent

The yellow coloring agent may be, for example, monoazo-based, disazo-based, condensation azo-based, benzimidazolone-based, iso-indolinone-based, or anthraquinone-based. Specific examples thereof include the following:

### (Anthraquinone-Based)

### Solvent Yellow 163, Pigment Yellow 24, Pigment Yellow 108, Pigment Yellow 193, Pigment Yellow 147, Pigment Yellow 199, and Pigment Yellow 202;

### (Iso-Indolinone-Based)

### Pigment Yellow 110, Pigment Yellow 109, Pigment Yellow 139, Pigment Yellow 179, and Pigment Yellow 185;

### (Condensed Azo-Based)

### Pigment Yellow 93, Pigment Yellow 94, Pigment Yellow 95, Pigment Yellow 128, Pigment Yellow 155, Pigment Yellow 166, and Pigment Yellow 180;

### (Benzimidazolone)

### Pigment Yellow 120, Pigment Yellow 151, Pigment Yellow 154, Pigment Yellow 156, Pigment Yellow 175, and Pigment Yellow 181;

### (Monoazo)

### Pigment Yellow 1, 2, 3, 4, 5, 6, 9, 10, 12, 61, 62, 62:1, 65, 73, 74, 75, 97, 100, 104, 105, 111, 116, 167, 168, 169, 182, 183; and

### (Disazo)

### Pigment Yellow 12, 13, 14, 16, 17, 55, 63, 81, 83, 87, 126, 127, 152, 170, 172, 174, 176, 188, 198.

### Red Coloring Agent

The red coloring agent may be, for example, monoazo-based, disazo-based, azo lake-based, benzimidazolone-based, perylene-based, diketopyrrolopyrrole-based, condensed azo-based, anthraquinone-based, or quinacridone-based, and specific examples thereof include the following:

### (Monoazo-Based)

### Pigment Red 1, 2, 3, 4, 5, 6, 8, 9, 12, 14, 15, 16, 17, 21, 22, 23, 31, 32, 112, 114, 146, 147, 151, 170, 184, 187, 188, 193, 210, 245, 253, 258, 266, 267, 268, and 269;

### (Disazo-Based)

### Pigment Red 37, 38, and 41;

### (Monoazo Lake)

### Pigment Red 48:1, 48:2, 48:3, 48:4, 49:1, 49:2, 50:1, 52:1, 52:2, 53:1, 53:2, 57:1, 58:4, 63:1, 63:2, 64:1, and 68;

### (Benzimidazolone)

### Pigment Red 171, Pigment Red 175, Pigment Red 176, Pigment Red 185, and Pigment Red 208;

### (Perylene)

### Solvent Red 135, Solvent Red 179, Pigment Red 123, Pigment Red 149, Pigment Red 166, Pigment Red 178, Pigment Red 179, Pigment Red 190, Pigment Red 194, and Pigment Red 224;

### (Diketopyrrolopyrrole-Based)

### Pigment Red 254, Pigment Red 255, Pigment Red 264, Pigment Red 270, and Pigment Red 272;

### (Condensed Azo-Based)

### Pigment Red 220, Pigment Red 144, Pigment Red 166, Pigment Red 214, Pigment Red 220, Pigment Red 221, and Pigment Red 242;

### (Anthraquinone-Based)

### Pigment Red 168, Pigment Red 177, Pigment Red 216, Solvent Red 149, Solvent Red 150, Solvent Red 52, and Solvent Red 207; and

### (Quinacridone-Based)

### Pigment Red 122, Pigment Red 202, Pigment Red 206, Pigment Red 207, and Pigment Red 209.

In addition, for the purpose of adjusting the color, other coloring agents such as violet, orange, brown, and black ones may be added.

Specific examples of the other coloring agents include: Pigment Violet 19, 23, 29, 32, 36, 38, 42, Solvent Violet 13, 36; C.I. Pigment Orange 1, C.I. Pigment Orange 5, C.I. Pigment Orange 13, C.I. Pigment Orange 14, C.I. Pigment Orange 16, C.I. Pigment Orange 17, C.I. Pigment Orange 24, C.I. Pigment Orange 34, C.I. Pigment Orange 36, C.I. Pigment Orange 38, C.I. Pigment Orange 40, C.I. Pigment Orange 43, C.I. Pigment Orange 46, C.I. Pigment Orange 49, C.I. Pigment Orange 51, C.I. Pigment Orange 61, C.I. Pigment Orange 63, C.I. Pigment Orange 64, C.I. Pigment Orange 71, C.I. Pigment Orange 73; C.I. Pigment Brown 23, C.I. Pigment Brown 25; and C.I. Pigment Black 1, C.I. Pigment Black 7.

### (C) Photopolymerization Initiator

The photopolymerization initiator (C) is preferably at least one photopolymerization initiator selected from the group consisting of oxime ester-based photopolymerization initiators having a group expressed by the general formula (III), α-amino acetophenone-based photopolymerization initiators having the group expressed by the general formula (IV), and acylphosphine oxide-based photopolymerization initiators expressed by the general formula (V).

The oxime ester-based photopolymerization initiator having a group expressed by the general formula (III) is more preferably 2-(acetyloxyiminomethyl)thioxanthene-9-one expressed by the formula (VI), and a compound having a group expressed by the general formula (VII). Examples of commercial products include CGI-325, IRGACURE OXE01, and IRGACURE OXE02 manufactured by Ciba Specialty Chemicals. These oxime ester-based photopolymerization initiators may be used alone or in combination of two or more thereof.

Examples of the α-aminoacetophenone-based photopolymerization initiator having a group expressed by the general formula (IV) include 2-methyl-1-[4-(methylthio)phenyl]-2-morpholinopropanone-1,2-benzyl-2-dimethylamino-1-(4-morpholinophenyl)-butane-1-one, 2-(dimethylamino)-2-[(4-methylphenyl)methyl]-1-[4-(4-morpholinyl)phenyl]-1-butanone, and N,N-dimethylaminoacetophenone. Examples of commercial products include IRGACURE-907, IRGACURE-369, and IRGACURE-379 manufactured by Ciba Specialty Chemicals.

Examples of the acylphosphine oxide-based photopolymerization initiator having a group expressed by the general formula (V) include 2,4,6-trimethylbenzoyldiphenylphosphine oxide, bis(2,4,6-trimethylbenzoyl)-phenylphosphine oxide, and bis(2,6-dimethoxybenzoyl)-2,4,4-trimethyl-pentylphosphine oxide. Examples of commercial products include LUCIRIN TPO manufactured by BASF, and IRGACURE 819 manufactured by Ciba Specialty Chemicals.

The content of the photopolymerization initiator (C) can be selected from 0.01 to 30 parts by mass, preferably from 0.5 to 15 parts by mass with reference to 100 parts by mass of the carboxylic acid-containing resin (A). If the content is less than 0.01 parts by mass, photocurability on copper is insufficient, which results in peeling of the coating film or deterioration in the coating film such as chemical resistance, and therefore it is not desirable. On the other hand, if the content is more than 30 parts by mass, the photopolymerization initiator (C) intensely absorbs light on the surface of the solder resist coating film, which results in deterioration in the deep curability, and therefore it is not desirable.

When the oxime ester-based photopolymerization initiator having the group expressed by the general formula (III) is used, the content is preferably selected from 0.01 to 20 parts by mass, and more preferably from 0.01 to 5 parts by mass with reference to 100 parts by mass of the carboxylic acid-containing resin (A).

The composition of the present invention may further contain other compounds as another photopolymerization initiator and a photoinitiator aid or a sensitizer. Examples of such other compounds include benzoin compounds, acetophenone compounds, anthraquinone compounds, thioxanthone compounds, ketal compounds, benzophenone compounds, xanthone compounds, and tertiary amine compounds.

Specific examples of the benzoin compounds include benzoin, benzoin methyl ether, benzoin ethyl ether, and benzoin isopropyl ether.

Specific examples of the acetophenone compounds include acetophenone, 2,2-dimethoxy-2-phenylacetophenone, 2,2-diethoxy-2-phenylacetophenone, and 1,1-dichloroacetophenone.

Specific examples of the anthraquinone compounds include 2-methylanthraquinone, 2-ethylanthraquinone, 2-t-butylanthraquinone, and 1-chloroanthraquinone.

Specific examples of the thioxanthone compounds include 2,4-dimethylthioxanthone, 2,4-diethylthioxanthone, 2-chlorothioxanthone, and 2,4-diisopropylthioxanthone.

Specific examples of the ketal compounds include acetophenone dimethyl ketal and benzyl dimethyl ketal.

Specific examples of the benzophenone compounds include benzophenone, 4-benzoyl diphenyl sulfide, 4-benzoyl-4′-methyldiphenyl sulfide, 4-benzoyl-4′-ethyldiphenyl sulfide, and 4-benzoyl-4′-propyldiphenyl sulfide.

Specific examples of the tertiary amine compounds include: ethanolamine compounds; compounds having a dialkylaminobenzene structure, for example, dialkylaminobenzophenone such as 4,4′-dimethylaminobenzophenone (NISSO CURE MABP manufactured by Nippon Soda Co., Ltd.) and 4,4′-diethylaminobenzophenone (EAB manufactured by Hodogaya Chemical Co., Ltd.); coumarin compounds containing a dialkylamino group such as 7-(diethylamino)-4-methyl-2H-1-benzopyran-2-one (7-(diethylamino)-4-methylcoumarin); ethyl 4-dimethylaminobenzoate (KAYACURE EPA manufactured by Nippon Kayaku Co., Ltd.); ethyl 2-dimethylaminobenzoate (Quantacure DMB manufactured by International Biosynthetic Inc.); (n-butoxy)ethyl 4-dimethylaminobenzoate (Quantacure BEA manufactured by International Biosynthetic Inc.) isoamyl p-dimethylaminobenzoate ethyl ester (KAYACURE DMBI manufactured by Nippon Kayaku Co., Ltd.), 2-ethylhexyl4-dimethylaminobenzoate (Esolol 507 manufactured by Van Dyk), and 4,4′-diethylaminobenzophenone (EAB manufactured by Hodogaya Chemical Co., Ltd.).

Among the above compounds, thioxanthone compounds and tertiary amine compounds are preferred. Inclusion of a thioxanthone compound is desirable from the viewpoint of deep curability. Particularly preferred are thioxanthone compounds such as 2,4-dimethylthioxanthone, 2,4-diethylthioxanthone, 2-chlorothioxanthone, and 2,4-diisopropylthioxanthone.

The content of the thioxanthone compound is preferably 20 parts by mass or less, and more preferably 10 parts by mass or less with reference to 100 parts by mass of the carboxylic acid-containing resin (A). If the content of the thioxanthone compound is too high, curability of a thick film deteriorates, which results in an increase in the production cost, and therefore it is not desirable.

The tertiary amine compound preferably has a dialkylamino benzene structure, and is particularly preferably a dialkylaminobenzophenone compound or a dialkylamino group-containing coumarin compound having a maximum absorption wavelength at 350 to 410 nm. The dialkylamino benzophenone compound is preferably 4,4′-diethylamino benzophenone because it is less toxic. The dialkylamino group-containing coumarin compound having a maximum absorption wavelength at 350 to 410 nm is less colored because it has a maximum absorption in the ultraviolet region, and thus allows to provide a colorless transparent photosensitive composition, as well as a color solder resist film, using the color of the pigment, reflecting the color of the pigment itself. Particularly preferred is 7-(diethylamino)-4-methyl-2H-1-benzopyran-2-one because it exhibits an excellent sensitizing effect to laser beams having a wavelength of 400 to 410 nm.

The content of the tertiary amine compound is preferably from 0.1 to 20 parts by mass, and more preferably from 0.1 to 10 parts by mass with reference to 100 parts by mass of the carboxylic acid-containing resin (A). If the content of the tertiary amine compound is less than 0.1 parts by mass, the sensitizing effect tends to be insufficient. On the other hand, if the content is more than 20 parts by mass, the tertiary amine compound intensely absorbs light on the surface of the dry solder resist coating film, which tends to result in deterioration in deep curability.

The photopolymerization initiator, photoinitiator aid, and sensitizer may be used alone or in combination of two or more thereof.

(D) Compound Having Two or More Ethylenically Unsaturated Groups within One Molecule Thereof

The compound (D) having two or more ethylenically unsaturated groups within one molecule thereof, which is used in the photocurable resin composition of the present invention, is photocured by irradiation with active energy beams, and insolubilizes or helps insolubilize the carboxylic acid-containing resin (A) in an alkali aqueous solution. Examples of the compound include: glycol diacrylates such as ethylene glycol, methoxytetraethylene glycol, polyethylene glycol, and propylene glycol; polyvalent acrylates of polyhydric alcohol or ethylene oxide adducts or propylene oxide adducts thereof such as hexanediol, trimethylolpropane, pentaerythritol, dipentaerythritol, tris-hydroxy ethyl isocyanurate; polyvalent acrylates such as phenoxy acrylate, bisphenol A diacrylate, and ethylene oxide adducts or propylene oxide adducts of these phenols; polyvalent acrylates of glycidyl ether such as glycerol diglycidyl ether, glycerol triglycidyl ether, trimethylolpropane triglycidyl ether, and triglycidyl isocyanurate; and melamine acrylate and/or each methacrylate of the above acrylates.

Other examples include epoxy acrylate resins prepared by reaction of a polyfunctional epoxy resin such as a cresol novolac type epoxy resin with acrylic acid, and epoxy urethane acrylate compounds prepared by reaction of the hydroxy group of the epoxy acrylate resin with a half urethane compound prepared from a hydroxy acrylate such as pentaerythritol triacrylate and a diisocyanate such as isophorone diisocyanate. These epoxy acrylate-based resins improve photocurability without deteriorating the dry tack.

The content of the compound (D) having two or more ethylenically unsaturated groups within one molecule thereof is from 5 to 100 parts by mass, and more preferably from 1 to 70 parts by mass with reference to 100 parts by mass of the carboxylic acid-containing resin (A). If the content is less than 5 parts by mass, photocurability deteriorates, which results in difficulty of pattern formation by alkali development after irradiation with active energy beams, and therefore it is not desirable. On the other hand, if the content is more than 100 parts by mass, solubility in an alkali aqueous solution deteriorates, which results in brittleness of the coating film, and therefore it is also not desirable.

(E) Thermosetting Component

The photocurable resin composition of the present invention may contain a thermosetting component to obtain heat resistance. Particularly preferred is a thermosetting component (E) having two or more cyclic ether groups and/or cyclic thioether groups (hereinafter abbreviated as cyclic (thio)ether groups) within one molecule thereof.

The thermosetting component (E) having two or more cyclic (thio)ether groups within one molecule thereof is a compound having two or more 3, 4, or 5-membered cyclic ether groups and/or cyclic thioether groups within one molecule thereof. Examples of the compound include a compound having two or more epoxy groups within one molecule thereof, more specifically, a polyfunctional epoxy compound (E1), a compound having two or more oxetanyl groups within one molecule thereof, and more specifically, a polyfunctional oxetane compound (E2), and a compound having two or more thioether groups within one molecule thereof, more specifically, an episulphide resin (E3).

Examples of the polyfunctional epoxy compound (E1) include, but are not limited to: bisphenol A type epoxy resins such as EPICOAT 828, EPICOAT 834, EPICOAT 1001, and EPICOAT 1004 manufactured by Japan Epoxy Resins Co., Ltd., EPICLON 840, EPICLON 850, EPICLON 1050, and EPICLON 2055 manufactured by Dainippon Ink And Chemicals, Incorporated, EPOTOHTO YD-011, YD-013, YD-127, and YD-128 manufactured by Tohto Kasei Co., Ltd., D.E.R. 317, D.E.R. 331, D.E.R. 661, and D.E.R. 664 manufactured by The Dow Chemical Company, ARALDITE 6071, ARALDITE 6084, ARALDITE GY250, and ARALDITE GY260 manufactured by Ciba Specialty Chemicals, SUMI-EPOXY ESA-011, ESA-014, ELA-115, and ELA-128 manufactured by Sumitomo Chemical Co., Ltd., and A.E.R. 330, A.E.R. 331, A.E.R. 661, and A.E.R. 664 manufactured by Asahi Chemical Industry Co., Ltd. (all product names are trade names); brominated epoxy resins such as EPICOAT YL903 manufactured by Japan Epoxy Resins Co., Ltd., EPICLON 152 and EPICLON 165 manufactured by Dainippon Ink And Chemicals, Incorporated, EPOTOHTO YDB-400 and YDB-500 manufactured by Tohto Kasei Co., Ltd., D.E.R. 542 manufactured by The Dow Chemical Company, ARALDITE 8011 manufactured by Ciba Specialty Chemicals, SUMI-EPOXY ESB-400 and ESB-700 manufactured by Sumitomo Chemical Co., Ltd., and A.E.R. 711 and A.E.R. 714 manufactured by Asahi Chemical Industry Co., Ltd. (all product names are trade names); novolac type epoxy resins such as EPICOAT 152 and EPICOAT 154 manufactured by Japan Epoxy Resins Co., Ltd., D.E.N. 431 and D.E.N. 438 manufactured by The Dow Chemical Company, EPICLON N-730, EPICLON N-770, and EPICLON N-865 manufactured by Dainippon Ink And Chemicals, Incorporated, EPOTOHTO YDCN-701 and YDCN-704 manufactured by Tohto Kasei Co., Ltd., ARALDITE ECN1235, ARALDITE ECN1273, ARALDITE ECN1299, and ARALDITE XPY307 manufactured by Ciba Specialty Chemicals, EPPN-201, EOCN-1025, EOCN-1020, EOCN-104S, and RE-306 manufactured by Nippon Kayaku Co., Ltd., SUMI-EPOXY ESCN-195X and ESCN-220 manufactured by Sumitomo Chemical Co., Ltd., and A.E.R. ECN-235 and ECN-299 manufactured by Asahi Chemical Industry Co., Ltd. (all product names are trade names); bisphenol F type epoxy resins such as EPICLON 830 manufactured by Dainippon Ink And Chemicals, Incorporated, EPICOAT 807 manufactured by Japan Epoxy Resins Co., Ltd., EPOTOHTO YDF-170, YDF-175, and YDF-2004 manufactured by Tohto Kasei Co., Ltd., and ARALDITE XPY306 manufactured by Ciba Specialty Chemicals (all product names are trade names); hydrogenated bisphenol A type epoxy resins such as EPOTOHTO ST-2004, ST-2007, and ST-3000 (trade names) manufactured by Tohto Kasei Co., Ltd.; glycidylamine type epoxy resins such as EPICOAT 604 manufactured by Japan Epoxy Resins Co., Ltd., EPOTOHTO YH-434 manufactured by Tohto Kasei Co., Ltd., ARALDITE MY720 manufactured by Ciba Specialty Chemicals, and SUMI-EPOXY ELM-120 manufactured by Sumitomo Chemical Co., Ltd. (all product names are trade names); hydantoin type epoxy resins such as ARALDITE CY-350 (trade name) manufactured by Ciba Specialty Chemicals; alicyclic epoxy resins such as CELLOXIDE 2021 manufactured by Daicel Chemical Industries, Ltd., and ARALDITE CY175 and CY179 manufactured by Ciba Specialty Chemicals (all product names are trade names); trihydroxyphenylmethane type epoxy resins such as YL-933 manufactured by Japan Epoxy Resins Co., Ltd., and T.E,N., EPPN-501, and EPPN-502 manufactured by The Dow Chemical Company (all product names are trade names); bixylenol type or biphenol type epoxy resins such as YL-6056, YX-4000, and YL-6121 manufactured by Japan Epoxy Resins Co., Ltd. (all product names are trade names), or mixtures thereof; bisphenol S type epoxy resins such as EBPS-200 manufactured by Nippon Kayaku Co., Ltd., EPX-30 manufactured by Asahi Denka Company Limited, EXA-1514 manufactured by Dainippon Ink And Chemicals, Incorporated (trade names); bisphenol A novolac type epoxy resins such as EPICOAT 157S (trade name) manufactured by Japan Epoxy Resins Co., Ltd.; tetraphenylolethane type epoxy resins such as EPICOAT YL-931 manufactured by Japan Epoxy Resins Co., Ltd., and ARALDITE 163 manufactured by Ciba Specialty Chemicals (all product names are trade names); heterocyclic epoxy resins such as ARALDITE PT810 manufactured by Ciba Specialty Chemicals, and TEPIC manufactured by Nissan Chemical Industries, Ltd. (all product names are trade names); diglycidyl phthalate resins such as BLEMMER DGT manufactured by NOF Corporation; tetraglycidyl xylenoylethane resins such as ZX-1063 manufactured by Tohto Kasei Co., Ltd.; naphthalene group-containing epoxy resins such as ESN-190 and ESN-360 manufactured by Nippon Steel Chemical Co., Ltd., and HP-4032, EXA-4750, and EXA-4700 manufactured by Dainippon Ink And Chemicals, Incorporated; epoxy resins having a dicyclopentadiene skeleton such as HP-7200 and HP-7200H manufactured by Dainippon Ink And Chemicals, Incorporated; glycidyl methacrylate copolymer-based epoxy resins such as CP-50S and CP-50M manufactured by NOF Corporation; cyclohexyl maleimide/glycidyl methacrylate copolymer epoxy resins; and epoxy-modified polybutadiene rubber derivatives such as PB-3600 manufactured by Daicel Chemical Industries, Ltd., and CTBN-modified epoxy resins such as YR-102 and YR-450 manufactured by Tohto Kasei Co., Ltd. These epoxy resins may be used alone or in combination of two or more thereof. Among these resins, particularly preferred are novolac type epoxy resins, heterocyclic epoxy resins, bisphenol A type epoxy resins, and mixtures thereof.

Examples of the polyfunctional oxetane compound (E2) include: polyfunctional oxetanes such as bis[(3-methyl-3-oxetanylmethoxy)methyl]ether, bis[(3-ethyl-3-oxetannylmethoxy)methyl]ether, 1,4-bis[(3-methyl-3-oxetannylmethoxy)methyl]benzene, 1,4-bis[(3-ethyl-3-oxetannylmethoxy)methyl]benzene, (3-methyl-3-oxetanyl)methyl acrylate, (3-ethyl-oxetanyl)methyl acrylate, (3-methyl-3-oxetanyl)methyl methacrylate, (3-ethyl-3-oxetanyl)methyl methacrylate, and oligomers and copolymers thereof; and ether compounds of oxetane alcohol with a hydroxylic resin such as a novolac resin, poly(p-hydroxystyrene), cardo type bisphenol, calixarene, calix resorcin allene, or silsesquioxane. Other examples include copolymers of an unsaturated monomer having an oxetane ring with alkyl (meth)acrylate.

Examples of the compound (E3) having two or more cyclic thioether groups within one molecule thereof include bisphenol A type episulfide resin YL7000 manufactured by Japan Epoxy Resins Co., Ltd. Other examples include episulphide resins prepared by the same synthesis method, except that the oxygen atoms in the epoxy group of the novolac type epoxy resin are replaced with sulfur atoms.

The content of the thermosetting component (E) having two or more cyclic (thio)ether groups within one molecule thereof is preferably from 0.6 to 2.5 equivalents, and more preferably from 0.8 to 2.0 equivalents with reference to an equivalency of the carboxyl group of the carboxylic acid-containing resin of 1. If the content of the thermosetting component (E) having two or more cyclic (thio)ether groups within one molecule thereof is less than 0.6, carboxyl groups remain in the solder resist film, which results in deterioration in heat resistance, alkali resistance, and electrical insulation, and therefore it is not desirable. On the other hand, if the content is more than 2.5 equivalents, cyclic (thio)ether groups having a low molecular weight remain in the dry coating film, which results in deterioration in the strength of the coating film, and therefore it is also not desirable.

The thermosetting component (E) having two or more cyclic (thio)ether groups within one molecule thereof is preferably combined with a thermosetting catalyst. Examples of the thermosetting catalyst include: imidazole and imidazole derivatives such as 2-methylimidazole, 2-ethylimidazole, 2-ethyl-4-methylimidazole, 2-phenylimidazole, 4-phenylimidazole, 1-cyanoethyl-2-phenylimidazole, 1-(2-cyanoethyl)-2-ethyl-4-methylimidazole; amine compounds such as dicyandiamide, benzyl dimethylamine, 4-(dimethylamino)-N,N-dimethylbenzylamine, 4-methoxy-N,N-dimethyl-)benzylamine, and 4-methyl-N,N-dimethylbenzylamine; hydrazine compounds such as adipic acid dihydrazide and sebacic acid dihydrazide; and phosphorus compounds such as triphenyl phosphine. Examples of commercial products include: 2MZ-A, 2MZ-OK, 2PHZ, 2P4BHZ, and 2P4 MHZ manufactured by Shikoku Chemicals Corporation (all product names are trade names of imidazole-based compounds); and U-CAT3503N and U-CAT3502T (all product names are trade names of block isocyanate compounds of dimethylamine), DBU, DBN, U-CATSA102, and U-CAT5002 (all products are dicyclic amidine compounds and salts thereof) manufactured by San-Apro Ltd. The catalyst is not limited to these examples, and may be a thermosetting catalyst for epoxy resins and oxetane compounds, or one that promotes reaction of epoxy groups and/or oxetanyl groups with carboxyl groups. The catalysts may be used alone or in combination of two or more thereof. Further, the catalyst may be an S-triazine derivative such as guanamine, acetoguanamine, benzoguanamine, melamine, 2,4-diamino-6-methacryloyloxyethyl-5-triazine, 2-vinyl-4,6-diamino-5-triazine, 2-vinyl-4,6-diamino-5-triazine-isocyanuric acid adduct, or 2,4-diamino-6-methacryloyloxyethyl-5-triazine-isocyanuric acid adduct. These compounds also impart adhesiveness, and are preferably combined with the above-described thermosetting catalyst.

The content of the thermosetting catalyst may be at an ordinary ratio, and is preferably, for example, from 0.1 to 20 parts by mass, and more preferably 0.5 to 15.0 parts by mass with reference to 100 parts by mass of the carboxylic acid-containing resin (A) or the thermosetting component (E) having two or more cyclic (thio)ether groups within one molecule thereof.

### Filler

As necessary, the photocurable resin composition of the present invention may contain a filler, thereby improving the physical strength and other properties of the coating film. The filler may be a known inorganic or organic filler, and is particularly preferably barium sulfate, spherical silica, or talc. Other examples include compounds having one or more ethylenically unsaturated groups, and the polyfunctional epoxy resin (E1) containing dispersed nanosilica, such as NANOCRYL (trade name) XP 0396, XP 0596, XP 0733, XP 0746, XP 0765, XP0768, XP 0953, XP0954, XP 1045 (all names are product grade names), NANOPOX (trade name) XP 0516, XP 0525, XP 0314 (all names are product grade names) manufactured by Hanse-Chemie AG. These fillers may be used alone or in combination of two or more thereof.

The content of the filler is preferably 300 parts by mass or less, more preferably from 0.1 to 300 parts by mass, and particularly preferably from 0.1 to 150 parts by mass with reference to 100 parts by mass of the carboxylic acid-containing resin (A). If the content of the filler is more than 300 parts by mass, the resultant photocurable resin composition has excessive viscosity, which results in the deterioration in printing properties and brittleness of the cured product, and therefore it is not desirable.

### Organic Solvent

Further, the photocurable resin composition of the present invention may contain an organic solvent used for the synthesis of the carboxylic acid-containing resin (A), the control of the composition, or the viscosity control before application to a substrate or a carrier film.

Examples of the organic solvent include ketones, aromatic hydrocarbons, glycol ethers, glycol ether acetates, esters, alcohols, aliphatic hydrocarbons, and petroleum solvents. Specific examples include ketones such as methyl ethyl ketone and cyclohexanone; aromatic hydrocarbons such as toluene, xylene, and tetramethylbenzene; glycol ethers such as cellosolve, methyl cellosolve, butyl cellosolve, carbitol, methyl carbitol, butyl carbitol, propylene glycol monomethyl ether, dipropylene glycol monomethyl ether, dipropylene glycol diethyl ether, and triethylene glycol monoethyl ether; esters such as ethyl acetate, butyl acetate, dipropylene glycol methyl ether acetate, propylene glycol methyl ether acetate, propylene glycol ethyl ether acetate, and propylene glycol butyl ether acetate; alcohols such as ethanol, propanol, ethylene glycol, and propylene glycol; aliphatic hydrocarbons such as octane and decane; and petroleum solvents such as petroleum ether, petroleum naphtha, hydrogenated petroleum naphtha, and solvent naphtha. These organic solvents may be used alone or in combination of two or more thereof.

### Other Ingredients

As necessary, the photocurable resin composition of the present invention may further contain known additives, for example: heat polymerization inhibitors such as hydroquinone, hydroquinone monomethyl ether, t-butylcatechol, pyrogallol, and phenothiazine; thickening agents such as fine powder silica, organic bentonite, and montmorillonite; anti-foaming agents and/or leveling agents such as silicon-based, fluorine-based, and polymer-based ones; silane coupling agents such as imidazole-based, thiazole-based, and triazole-based ones; antioxidants; and rust-preventive agents.

The photocurable resin composition of the present invention may further contain, without defeating the object of the invention, other photopolymerization initiators, photoinitiator aids, and sensitizers such as benzoin compounds, acetophenone compounds, anthraquinone compounds, thioxanthone compounds, ketal compounds, benzophenone compounds, xanthone compounds, and tertiary amine compounds.

The photocurable resin composition of the present invention preferably has a green or blue color. The color can be produced through the use of a single coloring agent or a mixture of a plurality of coloring agents.

### Dry Film, Cured Product, Printed Circuit Board

The photocurable resin composition of the present invention produced as described above is applied to a carrier film and dried thereon by an ordinary means, thereby forming a photocurable and thermosetting dry film.

The photocurable resin composition of the present invention or its dry film is photocured on copper to form a cured product. The composition may be photocured with an ultraviolet exposure device, or a laser beam source, in particular, laser beams having a wavelength of 350 to 410 nm. The printed circuit board according to the present invention is produced through thermal curing after the photocuring.

Specifically, the dry film, cured product, and printed circuit board are formed as follows. Firstly, the photocurable resin composition of the present invention is adjusted to have a viscosity suitable for any application method with, for example, the above-described organic solvent, applied to a base material by, for example, dip coating, flow coating, roll coating, bar coating, screen printing, or curtain coating, and then the organic solvent contained in the composition is dried by volatilization (predried) at a temperature of about 60 to 100° C., thereby forming a tack-free coating film. Alternatively, the composition is applied to a carrier film, dried thereon, and the film is wound and overlaid on the base material, thereby forming an insulating resin layer. Thereafter, the coating film is subjected to exposure to active energy beams or direct pattern exposure to a laser direct exposure device through a photomask having a pattern formed in a contact or non-contact manner, and the unexposed areas are developed with a rare alkali aqueous solution (for example, a 0.3 to 3% sodium carbonate aqueous solution) thereby forming a resist pattern. When the composition contains the thermosetting component (E), the composition is thermally cured by heating at a temperature of, for example, from about 140 to 180° C. to allow the carboxyl group of the carboxylic acid-containing resin (A) to react with the thermosetting component having two or more cyclic ether groups and/or cyclic thioether groups within one molecule thereof, thereby forming a cured coating film having properties such as excellent heat resistance, excellent chemical resistance, excellent moisture absorption resistance, excellent adhesiveness, and excellent electrical properties.

Even if the composition does not contain the thermosetting component (E), ethylenically unsaturated bonds remaining in an unreacted state after exposure cause heat radical polymerization through heat treatment, which results in an improvement in the coating film properties. Therefore, heat treatment (thermal curing) may be conducted according to the objective and intended use.

Examples of the base material include: copper clad laminates for high-frequency circuit of every glade (e.g., FR-4) composed of, for example, paper phenol, paper epoxy, glass fabric epoxy, glass polyimide, glass fabric/nonwoven fabric epoxy, glass fabric/paper epoxy, synthetic fiber epoxy, fluorine/polyethylene/PPO/cyanate ester; other polyimide films; PET films; a glass substrate; a ceramic substrate; and a wafer plate.

The drying by volatilization, carried out after application of the photosensitive composition of the present invention, may be carried out with a circulating hot air oven, an IR furnace, a hot plate, or a convection oven (under a method of counter-current-contacting hot air in a drying oven equipped with a heat source in a system of air heating with vapor or a system of blowing hot air against a support via a nozzle).

The photocurable resin composition of the present invention is applied as follows, dried by volatilization, and then the resultant coating film is subjected to exposure (irradiation with active energy beams). The exposed areas of the coating film (the areas irradiated with the active energy beams) are cured.

The exposure device used for the irradiation with active energy beams may be a laser direct imaging device, an exposure device equipped with a metal halide lamp, an exposure device equipped with a (ultra)high pressure mercury lamp, an exposure device equipped with a mercury short arc lamp, or a direct imaging device equipped with an ultraviolet light lamp such as a (ultra)high pressure mercury lamp. The active energy beams may be gas or solid laser beams as long as the maximum wavelength is within the range of 350 to 410 nm. The exposure dose is usually from 5 to 200 mJ/cm², preferably from 5 to 100 mJ/cm², and more preferably from 5 to 50 mJ/cm², though the range depends on the film thickness and other factors. The direct imaging device may be one manufactured by, for example, Orbotech Japan Co., Ltd. or HOYA Corporation, and may be any device as long as it emits laser beams having a maximum wavelength of 350 to 410 nm.

The development method may be, for example, a dipping method, a showering method, a spraying method, or a brushing method. The developing solution may be an alkaline aqueous solution of, for example, potassium hydroxide, sodium hydroxide, sodium carbonate, potassium carbonate, sodium phosphate, sodium silicate, ammonia, or an amine.

### EXAMPLES

The present invention is specifically described with reference to the following examples and comparative examples, but the present invention is not be limited to the following examples.

### Resin Composition Example 1

A 2-L separable flask equipped with a stirrer, a thermometer, a reflux condenser, a dropping funnel and a nitrogen inlet tube was charged with 660 g of a cresol novolac type epoxy resin (EOCN-104S, softening point 92° C., epoxy equivalent=220, manufactured by Nippon Kayaku Co., Ltd.), 421.3 g of carbitol acetate, and 180.6 g of solvent naphtha, and the mixture was heated and dissolved at 90° C. under stirring. Subsequently, the resulting solution was cooled once to 60° C., then 216 g of acrylic acid, 4.0 g of triphenyl phosphine, and 1.3 g of methyl hydroquinone were added thereto, and the mixture was allowed to react at 100° C. for 12 hours, whereby a reaction product having an acid value of 0.2 mgKOH/g was obtained. 241.7 g of tetrahydrophthalic anhydride was added to the product, and then allowed to react for 6 hours under heating at 90° C. As a result of this, a solution of the carboxylic acid-containing resin (A) having an acid value of 50 mgKOH/g, a double bond equivalent (weight (g) of the resin per mole of unsaturated group) of 400 g, and a weight average molecular weight of 7,000 was obtained. Hereinafter, the solution of the carboxylic acid-containing resin is referred to as A-1 varnish.

### Blending Example

The various components mentioned in the examples and comparative examples were premixed with a stirrer at the ratio of the blending example (parts by mass), and then kneaded with a three roll mill to produce a photosensitive resin composition for solder resist. The resultant photosensitive resin composition had a degree of dispersion of 15 μm or less as determined by particle size measurement with a grind meter manufactured by Erichsen.

In Comparative Examples 1 to 6, the “coloring agent (B) composed of a compound having an aminoantraquinone skeleton” according to the present invention was not added.

| Component A A-1varnish | 154 parts (solid | |
|---|---|---|
| | content 100 parts) | |
| Component B aminoantraquinone compound | | |
| (see table) | | |
| Component C photopolymerization initiator | | |
| (see table) | | |
| Component D dipentaerythritol hexaacrylate | 20 | parts |
| (DPHA/manufactured by Nippon Kayaku Co., Ltd.) | | |
| Component E phenol novolac type epoxy | 15 | parts |
| resin (DEN-431 manufactured by | | |
| The Dow Chemical Company) | | |
| Bixylenol type epoxy resin (YX-4000 manu- | 25 | parts |
| factured by Japan Epoxy Resins Co., Ltd.) | | |
| Other components | | |
| Barium sulfate (Barium Sulfate B30 manu- | 100 | parts |
| factured by Sakai Chemical Industry Co., Ltd.) | | |
| Thermosetting catalyst dicyandiamide Pigment | 0.3 | parts |
| (see table) | | |
| Silicon-based anti-foaming agent | 3 | parts |
| DPM (dipropylene glycol monomethyl ether) | 5 | parts |

TABLE 1

| Exposure to 355 nm laser | Example | | | | | Comparative Example | |
|---|---|---|---|---|---|---|---|
| Green solder resist | 1 | 2 | 3 | 4 | 5 | 1 | 2 |
| Photopolymerization initiator (C-1)*¹ | | | | | | | |
| Photopolymerization initiator (C-2)*² | 1.0 | 1.0 | 1.0 | 0.8 | 0.5 | 1.0 | 0.25 |
| Photopolymerization initiator (C-3)*³ | | | | | | | |
| Photopolymerization initiator (C-4)*⁴ | | | | | | | |
| Phthalocyanine blue | | | 0.1 | | 0.2 | 0.3 | 0.8 |
| C.I. Pigment Blue 15:3 | | | | | | | |
| Anthraquinone-based yellow pigment | | 0.5 | 0.5 | 0.8 | 0.8 | 0.5 | 0.8 |
| C.I. Pigment Yellow 147 | | | | | | | |
| Aminoantraquinone general formula (VIII) (green) | 0.8 | | | 0.3 | 0.3 | | |
| Aminoantraquinone general formula (IX) (blue) | | 0.4 | | 0.3 | 0.3 | | |
| Aminoantraquinone general formula (X) (blue) | | | 0.4 | 0.3 | | | |

TABLE 2

| Exposure to 355 nm laser | Example | | | | | Comparative Example | |
|---|---|---|---|---|---|---|---|
| Green solder resist | 1 | 2 | 3 | 4 | 5 | 1 | 2 |
| Color | Pale green | Pale green | Pale green | Green | Green | Pale green | Green |
| Sensitivity (mJ/cm²) | 25 | 25 | 25 | 30 | 50 | 40 | 100 |
| Dry tack | ⊚ | ◯ | Δ | ⊚ | ⊚ | X | X |
| Resolution (μm) | 50 | 50 | 50 | 50 | 50 | 100 | 100 |
| Line form | A | A | A | A or C | A or C | E | C |
| Solder heat resistance | ◯ | ◯ | ◯ | ◯ | ◯ | ◯ | ◯ |
| Electric corrosion resistance | ◯ | ◯ | ◯ | ◯ | ◯ | ◯ | ◯ |
| Electroless plating | ◯ | ◯ | ◯ | ◯ | ◯ | ◯ | ◯ |
| Acid resistance | ◯ | ◯ | ◯ | ◯ | ◯ | ◯ | ◯ |

The characteristic evaluation used a 355 nm laser exposure device manufactured by Orbotech Ltd.

TABLE 3

| Exposure to 355 nm laser | Example | | | | | Comparative Example | |
|---|---|---|---|---|---|---|---|
| Blue solder resist | 6 | 7 | 8 | 9 | 10 | 3 | 4 |
| Photopolymerization initiator (C-1)*¹ | 1.0 | | | | | | |
| Photopolymerization initiator (C-2)*² | | 1.0 | 1.0 | 0.8 | 0.5 | 1.0 | 0.25 |
| Photopolymerization initiator (C-3)*³ | | | | | | | |
| Photopolymerization initiator (C-4)*⁴ | | | | | | | |
| Phthalocyanine blue | | | 0.1 | | 0.3 | 0.3 | 0.8 |
| C.I. Pigment Blue 15:4 | | | | | | | |
| Aminoantraquinone general formula (VIII) (green) | | | | 0.4 | 0.2 | | |
| Aminoantraquinone general formula (IX) (blue) | 1.2 | 0.8 | | 0.5 | 0.5 | | |
| Aminoantraquinone general formula (X) (blue) | | | 0.8 | 0.5 | | | |

TABLE 4

| Exposure to 355 nm laser | Example | | | | | Comparative Example | |
|---|---|---|---|---|---|---|---|
| Blue solder resist | 6 | 7 | 8 | 9 | 10 | 3 | 4 |
| Color | Blue | Pale blue | Pale blue | Blue | Blue | Pale blue | Blue |
| Sensitivity (mJ/cm²) | 30 | 25 | 25 | 30 | 50 | 40 | 100 |
| Dry tack | ⊚ | ◯ | Δ | ⊚ | ⊚ | X | X |
| Resolution (μm) | 50 | 50 | 50 | 50 | 50 | 100 | 100 |
| Line form | A or C | A | A | A or C | A or C | E | C |
| Solder heat resistance | ◯ | ◯ | ◯ | ◯ | ◯ | ◯ | ◯ |
| Electric corrosion resistance | ◯ | ◯ | ◯ | ◯ | ◯ | ◯ | ◯ |
| Electroless plating | ◯ | ◯ | ◯ | ◯ | ◯ | ◯ | ◯ |
| Acid resistance | ◯ | ◯ | ◯ | ◯ | ◯ | ◯ | ◯ |

The characteristic evaluation used a 355 nm laser exposure device manufactured by Orbotech Ltd.

In Example 6, fine blue particles (about 30 μm) were found after the substrate was made.

TABLE 5

| | Example | | | | | Comparative Example | |
|---|---|---|---|---|---|---|---|
| Exposure to mercury short arc lamp | 11 | 12 | 13 | 14 | 15 | 5 | 6 |
| Photopolymerization initiator (C-1)*¹ | | | | | | | |
| Photopolymerization initiator (C-2)*² | | | | | | | |
| Photopolymerization initiator (C-3)*³ | | 15 | 15 | 15 | 15 | 15 | |
| Photopolymerization initiator (C-4)*⁴ | 10 | | | | | | 10 |
| Phthalocyanine blue | | | | | 0.3 | 0.3 | 0.7 |
| C.I. Pigment Blue 15:4 | | | | | | | |
| Anthraquinone-based yellow pigment | | 0.5 | | | 0.8 | 0.5 | 0.8 |
| C.I. Pigment Yellow 147 | | | | | | | |
| Aminoantraquinone general formula (VIII) (green) | 0.8 | | | 0.4 | 0.2 | | |
| Aminoantraquinone general formula (IX) (blue) | | 0.5 | 0.8 | 0.5 | 0.3 | | |
| Aminoantraquinone general formula (X) (blue) | | | | 0.5 | | | |

TABLE 6

| | Example | | | | | Comparative Example | |
|---|---|---|---|---|---|---|---|
| Exposure to mercury short arc lamp | 11 | 12 | 13 | 14 | 15 | 5 | 6 |
| Color | Pale green | Pale green | Pale blue | Blue | Green | Pale green | Green |
| Sensitivity (mJ/cm²) | 200 | 200 | 200 | 300 | 350 | 350 | 400 |
| Dry tack | ◯ | ◯ | ◯ | ⊚ | ⊚ | X | X |
| Resolution (μm) | 50 | 50 | 50 | 50 | 50 | 100 | 100 |
| Line form | A | A | A | A or C | A or C | A | E |
| Solder heat resistance | ◯ | ◯ | ◯ | ◯ | ◯ | ◯ | ◯ |
| Electric corrosion resistance | ◯ | ◯ | ◯ | ◯ | ◯ | ◯ | ◯ |
| Electroless plating | ◯ | ◯ | ◯ | ◯ | ◯ | ◯ | ◯ |
| Acid resistance | ◯ | ◯ | ◯ | ◯ | ◯ | ◯ | ◯ |

The characteristic evaluation used an exposure device equipped with a mercury short arc lamp manufactured by ORC Manufacturing Co., Ltd.

TABLE 7

| Exposure to 355 nm laser | Example | Example | Example | Example | Example | Example |
|---|---|---|---|---|---|---|
| Solder resist | 16 | 17 | 18 | 19 | 20 | 21 |
| Photopolymerization initiator (C-1)*¹ | 0.5 | 1.0 | | 0.5 | | 1 |
| Photopolymerization initiator (C-2)*² | 0.5 | | 0.5 | 0.5 | 0.5 | |
| Photopolymerization initiator (C-3)*³ | | | | | | |
| Photopolymerization initiator (C-4)*⁴ | | | | | | |
| Phthalocyanine blue | | 0.2 | 0.2 | | 0.2 | 0.4 |
| C.I. Pigment Blue 15:3 | | | | | | |
| Anthraquinone-based yellow pigment | | 0.4 | 0.6 | | | |
| C.I. Pigment Yellow 147 | | | | | | |
| Aminoantraquinone general formula (VIII) (green) | 0.4 | | 0.4 | | 0.2 | |
| Aminoantraquinone general formula (IX) (blue) | | | | 0.4 | 0.4 | 0.3 |
| Aminoantraquinone general formula (XI) (blue) | | | | 0.4 | 0.4 | |
| Aminoantraquinone general formula (X) (blue) | | | | 0.4 | | |
| Aminoantraquinone general formula (XII) (green) | 0.4 | 0.3 | | | | |
| Aminoantraquinone general formula (XIII) (green) | 0.4 | 0.3 | | | | |

TABLE 8

| | Example | Example | Example | Example | Example | Example |
|---|---|---|---|---|---|---|
| Exposure to 355 nm laser | 16 | 17 | 18 | 19 | 20 | 21 |
| Color | Green | Green | Green | Blue | Blue | Blue |
| L* value | 40.2 | 48.5 | 46.8 | 40.0 | 41.3 | 46.0 |
| a* value | −17.5 | −16.3 | −18.2 | −10.6 | −16.5 | −18.3 |
| b* value | 8.4 | 16.5 | 12.6 | −15.4 | −11.8 | −8.5 |
| Sensitivity (mJ/cm²) | 25 | 50 | 50 | 25 | 50 | 50 |
| Dry tack | ⊚ | ⊚ | ◯ | ⊚ | ⊚ | ◯ |
| Resolution (μm) | 50 | 50 | 50 | 50 | 50 | 50 |
| Line form | A | A | A | A | A | A |
| Solder heat resistance | ◯ | ◯ | ◯ | ◯ | ◯ | ◯ |
| Electric corrosion resistance | ◯ | ◯ | ◯ | ◯ | ◯ | ◯ |
| Electroless plating | ◯ | ◯ | ◯ | ◯ | ◯ | ◯ |
| Acid resistance | ◯ | ◯ | ◯ | ◯ | ◯ | ◯ |

The characteristic evaluation used a 355 nm laser exposure device manufactured by Orbotech Ltd.

TABLE 9

| | Example | Example | Example | Example | Example | Example |
|---|---|---|---|---|---|---|
| Exposure to mercury short arc lamp | 22 | 23 | 24 | 25 | 26 | 27 |
| Photopolymerization initiator (C-1)*¹ | 0.5 | 1 | | 0.5 | | 1 |
| Photopolymerization initiator (C-2)*² | 0.5 | | | 0.5 | | |
| Photopolymerization initiator (C-3)*³ | | | 15 | | 15 | |
| Photopolymerization initiator (C-4)*⁴ | | | | | | |
| Phthalocyanine blue | | 0.2 | 0.2 | | 0.2 | 0.4 |
| C.I. Pigment Blue 15:3 | | | | | | |
| Anthraquinone-based yellow pigment | | 0.4 | 0.6 | | | |
| C.I. Pigment Yellow 147 | | | | | | |
| Aminoantraquinone general formula (VIII) (green) | 0.4 | | 0.4 | | 0.2 | |
| Aminoantraquinone general formula (IX) (blue) | | | | 0.4 | 0.4 | 0.3 |
| Aminoantraquinone general formula (XI) (blue) | | | | 0.4 | 0.4 | |
| Aminoantraquinone general formula (X) (blue) | | | | 0.4 | | |
| Aminoantraquinone general formula (XII) (green) | 0.4 | 0.3 | | | | |
| Aminoantraquinone general formula (XIII) (green) | 0.4 | 0.3 | | | | |

TABLE 10

| | Example | Example | Example | Example | Example | Example |
|---|---|---|---|---|---|---|
| Exposure to mercury short arc lamp | 22 | 23 | 24 | 25 | 26 | 27 |
| Color | Green | Green | Green | Blue | Blue | Blue |
| L* value | 40.3 | 48.5 | 46.5 | 40.3 | 41.2 | 46.5 |
| a* value | −17.5 | −16.3 | −18.5 | −10.6 | −16.7 | −18.3 |
| b* value | 8.5 | 16.5 | 13.0 | −15.4 | −12.2 | −8.5 |
| Sensitivity (mJ/cm²) | 50 | 50 | 250 | 50 | 200 | 50 |
| Dry tack | ⊚ | ⊚ | ◯ | ⊚ | ⊚ | ◯ |
| Resolution (μm) | 50 | 50 | 50 | 50 | 50 | 50 |
| Line form | A | A | A or C | A | A | A |
| Solder heat resistance | ◯ | ◯ | ◯ | ◯ | ◯ | ◯ |
| Electric corrosion resistance | ◯ | ◯ | ◯ | ◯ | ◯ | ◯ |
| Electroless plating | ◯ | ◯ | ◯ | ◯ | ◯ | ◯ |
| Acid resistance | ◯ | ◯ | ◯ | ◯ | ◯ | ◯ |

The characteristic evaluation used an exposure device equipped with a mercury short arc lamp manufactured by ORC Manufacturing Co., Ltd.

*1: 2-(acetyloxyiminomethyl)thioxanthene-9-one
*2: ethanone,1[9-ethyl-6-(2-methylbenzoyl)-9H-carbazole-3-yl],1-(O-acetyloxime)
*3: 2,4,6-trimethylbenzoyl-diphenyl-phosphine oxide
*4: Irg.369 (manufactured by Ciba Specialty Chemicals)

The characteristic evaluation used EXP-2960 manufactured by ORC.

The aminoantraquinone-based coloring agents used in Examples are expressed by the formulae (VIII), (IX), (X), (XI), (XII), and (XIII), respectively.

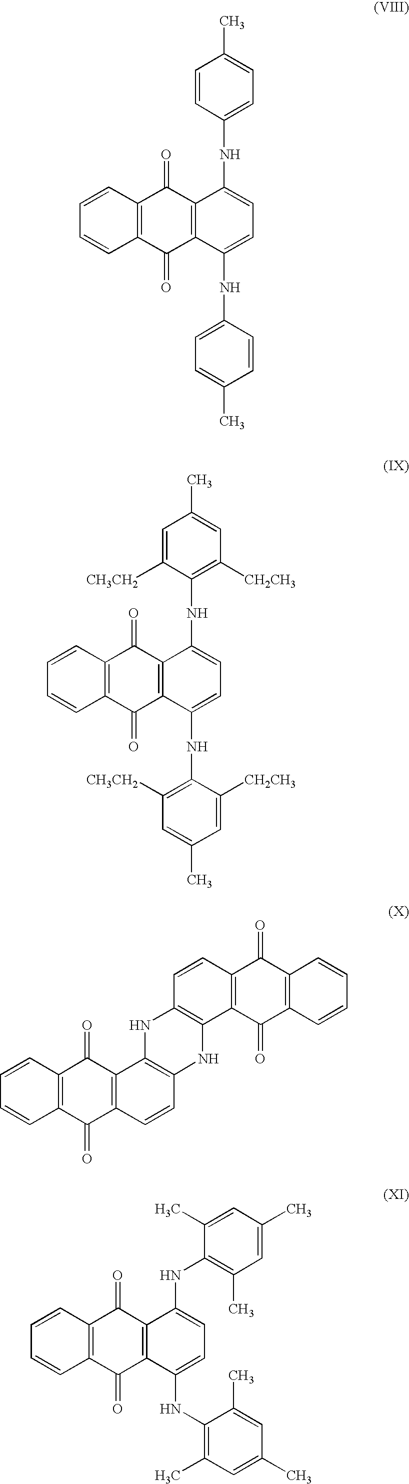

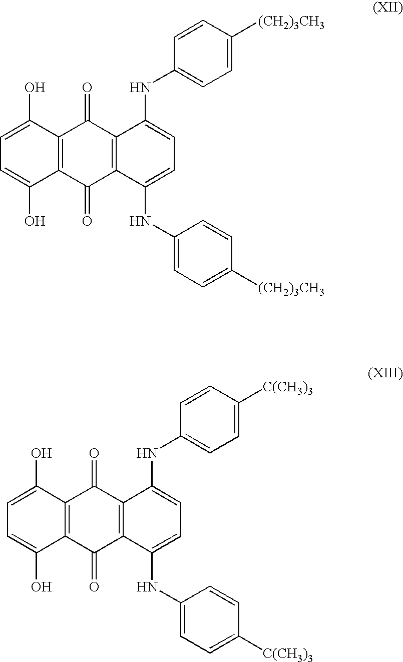

### Performance Evaluation

### <Optimum Exposure Dose/Sensitivity>

Circuit pattern substrates having a copper thickness of 35 μm were polished by buff-rolling, washed with water, and dried. Thereafter, the photocurable resin compositions of the examples and comparative examples were individually applied to the entire surface of the substrates by screen printing, and then dried for 60 minutes in a circulating hot air oven at 80° C. After drying, the dry coating was subjected to light exposure with a direct imaging device equipped with a semiconductor laser having a maximum wavelength of 355 nm or an exposure device equipped with a mercury short arc lamp via a step tablet (Kodak No. 2), and developed (30° C., 0.2 MPa, 1% by mass sodium carbonate aqueous solution) for 60 seconds. When the residual pattern of the step tablet had 7 steps, the exposure dose was regarded as optimum.

### <Resolution and Line Form>

Circuit pattern substrates having a line/space width of 300/300 and a copper thicknesses of 35 μm were polished by buff-rolling, washed with water, and dried. Thereafter, the photocurable resin compositions of the examples and comparative examples were individually applied to the substrates by screen printing, and then dried for 60 minutes in a circulating hot air oven at 80° C. After drying, the dry coating was subjected to light exposure with a direct imaging device equipped with a semiconductor laser having a maximum wavelength of 355 nm or an exposure device equipped with a mercury short arc lamp. As the exposure pattern, 20/30/40/50/60/70/80/90/100 μm lines were drawn in a space according to direct imaging data or through a photomask. The active energy beams were radiated so as to give the optimum exposure dose for the photosensitive resin compositions. After the exposure, the pattern was formed through development with a 1% by mass sodium carbonate aqueous solution at 30° C., and subjected to thermal curing at 150° C. for 60 minutes to form a cured coating film.

The minimum residual line on the cured coating film of the resultant photocurable resin composition for solder resist was observed with an optical microscope at a magnification of 200 (resolution). Further, the center of the line was cut, the surface was subjected to mirror finishing, and then the upper and lower diameters of the minimum residual line on the cured coating film, and the film thickness were measured with an optical microscope at a magnification of 1000. The line forms were graded A to E as shown in Figures (line forms).

The forms were graded A to E. The grade A was given when the deviation from the designed value was less than 5 μm for both of the upper and lower lines.

Grade A: ideal state with width as designed;
Grade B: biting of the surface layer due to insufficient development resistance or the like;
Grade C: undercut state;
Grade D: line thickening due to halation or the like; and
Grade E: line thickening on the surface layer and undercut.

In addition to Grade A samples, those of Grades C and D are also acceptable as solder resists. On the other hand, Grade B samples exhibit insufficient surface curability, and have inferior appearance and electrical properties, and Grade E samples tend to cause peeling of the line and undercut portion. Therefore, they are unacceptable as solder resists.

### <Dry Tack>

The compositions of the examples and comparative examples were individually applied by screen printing to the entire surface of a copper foil substrate having a pattern, dried at 80° C. for 20 minutes, and allowed to cool to room temperature. A PET negative film was bonded to the substrate under reduced pressure for one minute using EXP-2960 manufactured by ORC. Thereafter, stickiness of the negative film during removal was evaluated as follows.

◯: removable without resistance;
Δ: removable but slightly remains on the coating film; and
X: resists removal, and appears to remain on the coating film.

### Characteristic Test

Making of sample substrate: the compositions of the examples and comparative examples were individually applied by screen printing to the entire surface of a copper foil substrate having a pattern, dried at 80° C. for 20 minutes, and allowed to cool to room temperature. The substrate was exposed to light at an optimum exposure dose according to a solder resist pattern using a direct imaging device equipped with a semiconductor laser having a maximum wavelength of 355 nm or an exposure device equipped with a mercury short arc lamp, and developed for 60 seconds with a spray of 1% Na₂CO₃ aqueous solution at 30° C. under a spray pressure of 0.2 MPa, thereby forming a resist pattern. The substrate was subjected to ultraviolet radiation in a UV conveyor furnace at an integrated exposure dose of 1000 mJ/cm², and then cured through heating at 150° C. for 60 minutes. The characteristics of the resultant print substrates (sample substrates) were evaluated as follows.

### <Color>

The cured products of the alkali development type solder resists of the examples and comparative examples were observed visually to determine their colors.

### <Solder Heat Resistance>

The sample substrates coated with a rosin-based flux were immersed in a solder bath preheated to 260° C., the flux was washed off with a modified alcohol, and then swelling and peeling of the resist layer was evaluated on the basis of visual observation. The evaluation criteria are as follows.

◯: no peeling after six repeats of immersion for 10 seconds;
Δ: slight peeling after six repeats of immersion for 10 seconds; and
X: swelling and peeling of the resist layer during six repeats of immersion for 10 seconds.

### <Resistance to Electroless Gold Plating>

Using a commercially available electroless nickel plating bath and an electroless gold plating bath, plating was carried out to form a 0.5 μm nickel film and a 0.03 μm gold film. The resist layer was inspected for peeling and impregnation with plating by tape peeling test. Subsequently, the substrate was immersed in a solder bath for 10 seconds, washed, and dried under the test conditions for the solder heat resistance. Thereafter, the resist layer was inspected for peeling by a tape peeling test. The evaluation criteria are as follows.

◯: no change after plating, and no peeling after soldering;
Δ: slight peeling and impregnation after plating, and peeling after soldering; and
X: peeling after plating.

### <Electric Corrosion Resistance>

Sample substrates were made under the above-described conditions using comb type electrode B coupons of IPC B-25 in place of the copper foil substrates. The comb type electrodes were subjected to a bias voltage of DC 100 V, and inspected for the occurrence of migration after immersion for 1,000 hours in a thermostat bath at 85° C. and 85% R.H. The evaluation criteria are as follows.

◯: substantially no change;
Δ: discoloration; and
X: occurrence of migration.

### <Acid Resistance>

The sample substrates were immersed for 30 minutes in a 10 vol % H₂SO₄ aqueous solution at room temperature, and inspected for impregnation, dissolution of the coating film, and peeling by a tape peeling test. The evaluation criteria are as follows.

◯: no impregnation, dissolution, or peeling;
Δ: slight impregnation, dissolution, or peeling; and
X: marked impregnation, dissolution, or peeling.

As is evident from the results shown in Tables 1 to 6, the examples according to the present invention had excellent sensitivity, dry tack, resolution, and line form. On the other hand, the comparative examples containing no coloring agent according to the present invention were inferior to the examples of the present invention in dry tack and resolution, and no better than the examples of the present invention in terms of any of sensitivity, dry tack, resolution, and line form.

As an additional test, test substrates were made from the compositions of Examples 11 to 15 using a direct imaging device equipped with a mercury short arc lamp (Mercurex manufactured by Dainippon Screen Mft. Co., Ltd.), in place of the exposure device equipped with an ultrahigh pressure mercury lamp. The results of the characteristic evaluation of the coating films were the same as those obtained for the substrates tested using the exposure device equipped with a mercury short arc lamp.

### <L*a*b* Measurement>

Coating films of the examples and comparative examples were made by the above-described method for making sample substrates. The film thickness was 25±2 μm after drying. The color of the resultant cured coating films was measured using a spectroscopic calorimeter. The spectroscopic colorimeter used was CM-2600d manufactured by Konica Minolta Holdings, and the calorimetric system used was CIE L*a*b*. The calorimetric data were measured in SCI mode on the surface of the uniform coating film (on copper circuit) on the copper foil substrates.

### EXAMPLES

Examples 23, 24, and 25 were exposed to light using a direct imaging device equipped with an ultrahigh pressure mercury lamp (Mercurex manufactured by Dainippon Screen Mft. Co., Ltd.) as the light source in place of the mercury short arc lamp; the results were substantially the same as those for Examples 23, 24, and 25.

### EXAMPLES

Photosensitive resin compositions prepared with the same recipe for Examples 16 and 23 were diluted with methyl ethyl ketone, applied to carrier films, and dried through heating thereby forming photosensitive resin composition layers having a thickness of 20 μm. The layers were dried for 30 minutes with a heat drier at 80° C. A cover film was bonded to each layer to produce a dry film. Thereafter, the cover film was removed, the film was thermally laminated to a copper foil substrate having a pattern, and then exposed to light in the same manner as described above. After the exposure, the carrier film was removed, the composition layer was thermally cured for 60 minutes with a hot-air drier at 150° C., whereby a test substrate was made. The resultant test substrates having a cured film were subjected to characteristic evaluation by the below-described test methods and evaluation methods. The results are equivalent to those for Examples 16 and 23.

### Comparative Examples

As commercial solder resists having good colors, various products of PSR-4000 manufactured by Taiyo Ink Mfg. Co., Ltd. were measured for their L*a*b* values (Table 11).

Usually, commercially available green solder resists have an L* value of 40 to 60, an a* value of −10 to −28, and a b* value of 6 to 18, and blue solder resists have an L* value of 40 to 60, an a* value of −10 to −28, and a b* value of −6 to −18, though the values vary depending on the film thickness and pretreatment of the copper substrate.

They had good colors, but were insufficiently sensitive to direct imaging exposure, which is the object of the present invention. They were all graded E in the evaluation of their resolution (line form) when subjected to 355 nm laser exposure (using Paragon 8000 manufactured by Orbotech Ltd).

TABLE 11

| Exposure to | PSR- | PSR- | PSR- | PSR- |
|---|---|---|---|---|
| 355 nm laser | 4000G23K | 4000GEC50 | 4000SP08 | 4000BEC50 |
| Color | Green | Green | Green | Blue |
| L* value | 54.9 | 47.7 | 57.2 | 46.2 |
| a* value | −22.4 | −21.8 | −13.3 | −21.2 |
| b* value | 14.7 | 13.7 | 17.7 | −6.5 |
| Sensitivity | 250 | 200 | 250 | 200 |
| (mJ/cm²) | | | | |
| Line form | E | E | E | E |

(Test example) Ultraviolet absorption properties of compounds of general formulae (VIII), (IX), and (XIII) in comparison with phthalocyanine blue (C.I. Pigment Blue 15:3)

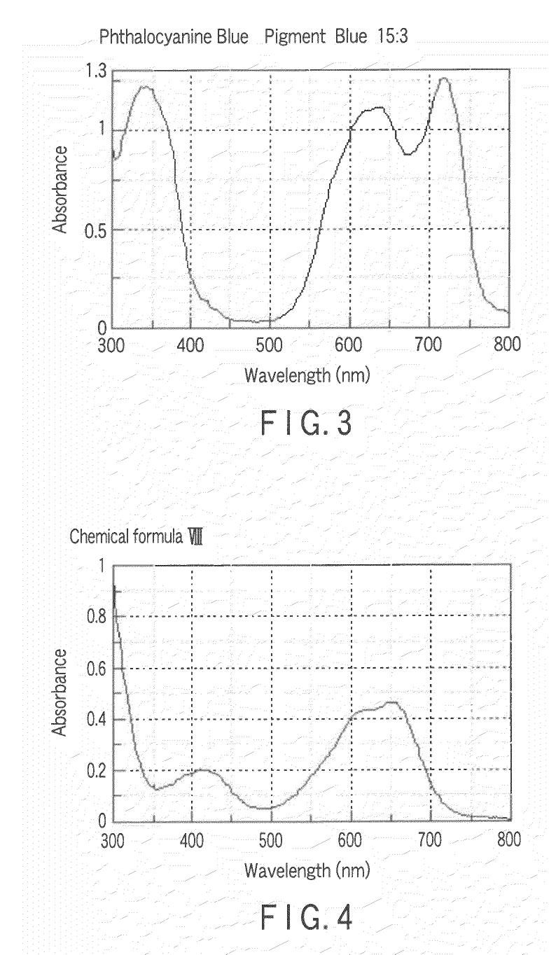

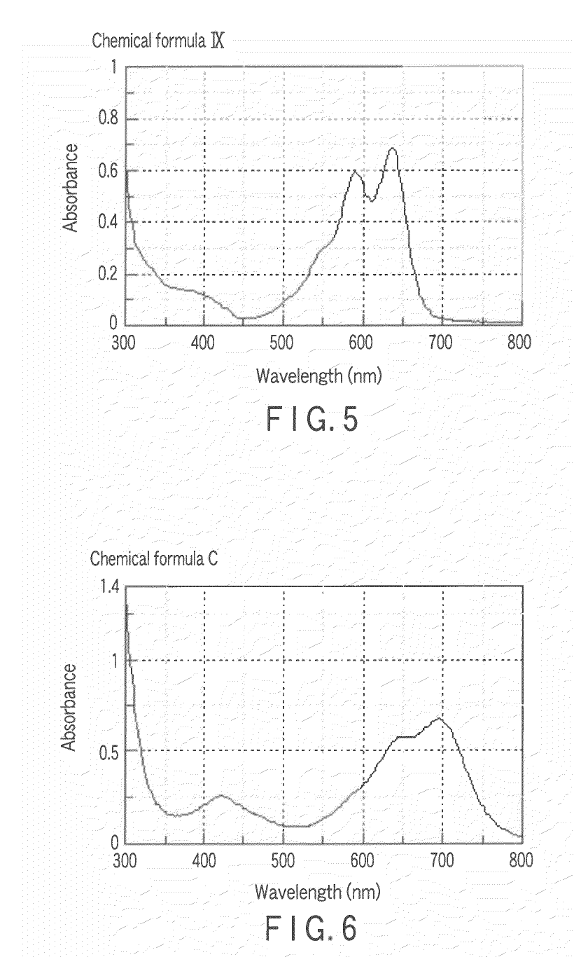

The above-described four coloring agents were added to and dispersed in the A-1 varnish such that the concentration of the coloring agent in the dry coating film was 0.85%. The resultant colored varnish was applied to a glass with an applicator such that the thickness of the dry coating film was 30 μm±2 μm. After drying the coating film at 80° C. for 30 minutes, its absorption spectrum was measured with an ultraviolet-visible spectrophotometer (Ubest-V-570DS manufactured by JASCO Corporation) and an integrating sphere device (ISN-470 manufactured by JASCO Corporation). The results are shown in FIGS. 3 to 6.

As is evident from the results shown in these Figures, the compounds expressed by the general formulae (VIII), (IX), and (XIII) have weaker absorptions within the range of 350 nm to 410 nm in comparison with phthalocyanine blue.

What is claimed is:

1. A photocurable resin composition developable with a rare alkali solution, comprising a carboxylic acid-containing resin (A), a coloring agent (B) composed of a compound having an aminoantraquinone skeleton, a photopolymerization initiator (C), and a compound (D) having two or more ethylenically unsaturated groups within one molecule thereof.

2. The photocurable resin composition according to claim 1 developable with a rare alkali solution, wherein the aminoantraquinone compound (B) is expressed by the general formula (I): 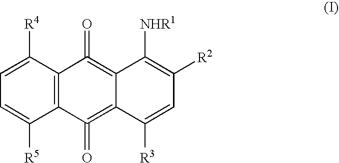
wherein R¹ represents a linear or branched alkyl group, an alkyl-substituted or unsubstituted phenyl group, a cyclohexyl group, a linear or branched alkyl group through the mediation of a carbonyl group, a substituted or unsubstituted phenyl group; R² represents a hydrogen atom, a hydroxy group, a cyclohexyl group, a linear or branched alkyl group, a substituted or unsubstituted phenyl group, the R² being bonded directly or through the mediation of an NH group, and the R² may be in the form a ring together with the R¹; R³, R⁴, and R⁵ each independently represent a hydrogen atom, a hydroxy group, a cyclohexyl group, a linear or branched alkyl group, a substituted or unsubstituted phenyl group, a linear or branched alkyl group through the mediation of an NH group, an alkyl-substituted or unsubstituted phenyl group, a cyclohexyl group, a linear or branched alkyl group through the mediation of an amide group, a substituted or unsubstituted phenyl group.

3. The photocurable resin composition according to claim 1 developable with a rare alkali solution, wherein the coloring agent (B) composed of a compound having an aminoantraquinone skeleton comprises two or more coloring agents having different structures.

4. The photocurable resin composition according to claim 1 developable with a rare alkali solution, wherein the coloring agent (B) composed of a compound having an aminoantraquinone skeleton is expressed by the general formula (II): 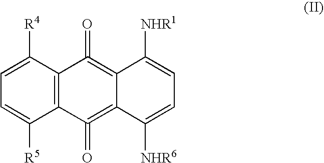
wherein R¹ represents a linear or branched alkyl group, an alkyl-substituted or unsubstituted phenyl group, a cyclohexyl group, a linear or branched alkyl group through the mediation of a carbonyl group, a substituted or unsubstituted phenyl group; R⁴ and R⁵ each independently represent a hydrogen atom, a hydroxy group, a cyclohexyl group, a linear or branched alkyl group, a substituted or unsubstituted phenyl group, a linear or branched alkyl group through the mediation of an NH group, an alkyl-substituted or unsubstituted phenyl group, a cyclohexyl group, a linear or branched alkyl group through the mediation of an amide group, a substituted or unsubstituted phenyl group; and R⁶ represents a linear or branched alkyl group, an alkyl-substituted or unsubstituted phenyl group, a cyclohexyl group, a linear or branched alkyl group through the mediation of a carbonyl group, a substituted or unsubstituted phenyl group.

5. The photocurable resin composition according to claim 1 developable with a rare alkali solution, wherein the coloring agent (B) composed of a compound having an aminoantraquinone skeleton is a single compound or mixture selected from the group consisting of coloring agents having green and blue colors.

6. The photocurable resin composition according to claim 1, wherein the photopolymerization initiator (C) is at least one selected from the group consisting of oxime ester-based photopolymerization initiators expressed by the general formula (III): 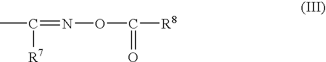
wherein R⁷ represents a hydrogen atom, a phenyl group (which may be substituted with an alkyl group having 1 to 6 carbon atoms, a phenyl group, or a halogen atom), an alkyl group having 1 to 20 carbon atoms (which may be substituted with one or more hydroxy groups, or contain one or more oxygen atoms in the middle of the alkyl chain), a cycloalkyl group having 5 to 8 carbon atoms, an alkanoyl group or benzoyl group having 2 to 20 carbon atoms (which may be substituted with an alkyl group having 1 to 6 carbon atoms or a phenyl group); R⁸ represents a phenyl group (which may be substituted with an alkyl group having 1 to 6 carbon atoms, a phenyl group, or a halogen atom), an alkyl group having 1 to 20 carbon atoms (which may be substituted with one or more hydroxy groups, or contain one or more oxygen atoms in the middle of the alkyl chain), a cycloalkyl group having 5 to 8 carbon atoms, an alkanoyl group or benzoyl group having 2 to 20 carbon atoms (which may be substituted with an alkyl group having 1 to 6 carbon atoms or a phenyl group);
α-amino acetophenone-based photopolymerization initiators expressed by the general formula (IV): 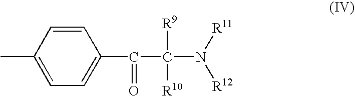
wherein R⁹ and R¹⁰ each independently represent an alkyl group or arylalkyl group having 1 to 12 carbon atoms, R¹¹ and R¹² are each independently a hydrogen atom, an alkyl group having 1 to 6 carbon atoms, or a cyclic alkyl ether group composed of two rings;
acyl phosphine oxide-based photopolymerization initiators expressed by the general formula (V): 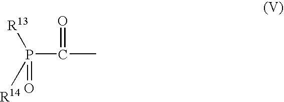
wherein R¹³ and R¹⁴ each independently represent a linear or branched alkyl group having 1 to 10 carbon atoms, a cyclohexyl group, a cyclopentyl group, an aryl group, an alkoxy group, or an aryl group substituted with a halogen atom, an alkyl group, or an alkoxy group, one of the R¹³ or R¹⁴ may represent an R—C(═O)-group (wherein R is a hydrocarbon group having 1 to 20 carbon atoms).

7. The photocurable resin composition according to claim 6, wherein the oxime ester-based photopolymerization initiator (C) expressed by the general formula (III) is expressed by the following formula (VI):

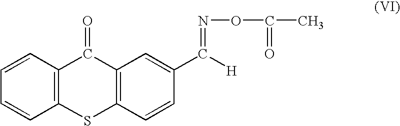

8. The photocurable resin composition according to claim 6, wherein the oxime ester-based photopolymerization initiator (C) expressed by the general formula (III) is expressed by the following formula (VII): 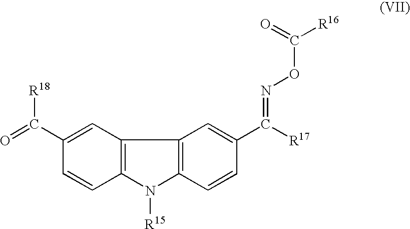
wherein R¹⁵ represents a hydrogen atom, a halogen atom, an alkyl group having 1 to 12 carbon atoms, a cyclopentyl group, a cyclohexyl group, a phenyl group, a benzyl group, a benzoyl group, an alkanoyl group having 2 to 12 carbon atoms, an alkoxycarbonyl group having 2 to 12 carbon atoms (when the alkoxyl group is composed of an alkyl group having 2 or more carbon atoms, the alkyl group may be substituted with one or more hydroxy groups, or contain one or more oxygen atoms in the middle of the alkyl chain), or a phenoxy carbonyl group; R¹⁶ and R¹⁸ each independently represent a phenyl group (which may be substituted with an alkyl group having 1 to 6 carbon atoms, a phenyl group, or a halogen atom), an alkyl group having 1 to 20 carbon atoms (which may be substituted with one or more hydroxy groups, or contain one or more oxygen atoms in the middle of the alkyl chain), a cycloalkyl group having 5 to 8 carbon atoms, an alkanoyl group or benzoyl group having 2 to 20 carbon atoms (which may be substituted with an alkyl group having 1 to 6 carbon atoms or a phenyl group), and R¹⁷ represents a hydrogen atom, a phenyl group (which may be substituted with an alkyl group having 1 to 6 carbon atoms, a phenyl group, or a halogen atom), an alkyl group having 1 to 20 carbon atoms (which may be substituted with one or more hydroxy groups, or contain one or more oxygen atoms in the middle of the alkyl chain), a cycloalkyl group having 5 to 8 carbon atoms, an alkanoyl group or benzoyl group having 2 to 20 carbon atoms (which may be substituted with an alkyl group having 1 to 6 carbon atoms or a phenyl group).

9. The photocurable resin composition according to claim 1, which further comprises a thermosetting component (E).

10. The photocurable resin composition according to claim 1, wherein the color of the composition is within the range of green to blue.

11. A photocurable dry film obtainable by applying the photocurable resin composition according to claim 1 to a carrier film, and then drying the coating film.

12. A cured product obtainable by photocuring the photocurable resin composition according to claim 1 on copper.

13. A cured product obtainable by photocuring the photocurable resin composition according to claim 1.

14. A printed circuit board obtainable by photocuring the photocurable resin composition according to claim 1, and then thermally curing the cured product.

15. A printed circuit board comprising the coloring agent according to claim 1 composed of a compound having an aminoantraquinone skeleton.

16. A cured product obtainable by photocuring the photocurable resin composition according to the dry film of claim 11 on copper.

17. A cured product obtainable by photocuring the photocurable resin composition according to the dry film of claim 11.

18. A printed circuit board obtainable by photocuring the photocurable resin composition according to the dry film of claim 11, and then thermally curing the cured product.
